(19) United States
(12) Patent Application Publication
(10) Pub. No.: US 2016/0148864 A1
(43) Pub. Date: May 26, 2016

(54) INTEGRATED DEVICE PACKAGE COMPRISING HETEROGENEOUS SOLDER JOINT STRUCTURE

(71) Applicant: QUALCOMM Incorporated, San Diego, CA (US)

(72) Inventors: Jie Fu, San Diego, CA (US); David Fraser Rae, San Diego, CA (US); Manuel Aldrete, Encinitas, CA (US); Vladimir Noveski, San Diego, CA (US); Chin-Kwan Kim, San Diego, CA (US)

(21) Appl. No.: 14/703,617

(22) Filed: May 4, 2015

Related U.S. Application Data
(60) Provisional application No. 62/083,054, filed on Nov. 21, 2014.

(51) Int. Cl. H01L 23/498; H01L 23/538; H01L 23/00

(52) U.S. Cl. CPC H01L 23/49833; H01L 24/17; H01L 24/32; H01L 24/73; H01L 24/81; H01L 24/83; H01L 24/92; H01L 23/5389; H01L 2224/73253; H01L 2224/92225; H01L 2224/16227; H01L 2224/32225; H01L 2924/152; H01L 2224/8385; H01L 2224/81801

(57) ABSTRACT

Some features pertain to an integrated circuit device that includes a first package substrate, a first die coupled to the first package substrate, a second package substrate, and a solder joint structure coupled to the first package substrate and the second package substrate. The solder joint structure includes a solder comprising a first melting point temperature, and a conductive material comprising a second melting point temperature that is less than the first melting point temperature. In some implementations, the conductive material is one of at least a homogeneous material and/or a heterogeneous material. In some implementations, the conductive material includes a first electrically conductive material and a second material. The conductive material is an electrically conductive material.

### CLAIM OF PRIORITY/CLAIM OF BENEFIT

The present application claims priority to U.S. Provisional Application No. 62/083,054 titled “Integrated Device Package Comprising Heterogeneous Solder Joint Structure”, filed Nov. 21, 2014, which is hereby expressly incorporated by reference herein.

### BACKGROUND

1. Field

Various features relate to an integrated device package that includes a heterogeneous solder joint structure.

2. Background

FIG. 1 illustrates a conventional device 100 that includes a first package 102 and an interposer 104. The first package 102 includes a first die 120 and a first package substrate 122. The first package substrate 122 includes a first set of pads 124 and a second set of pads 126, which includes pad 126. The first package substrate 122 may include one or more dielectric layers. The first die 120 is coupled to the first package substrate 122 through a first set of solder balls 128. Specifically, the first die 120 is coupled to the first set of pads 124 through the first set of solder balls 128. A second set of solder balls 130 is coupled to the first package substrate 122.

The interposer 104 includes a third set of pads 144, which includes pad 144. The interposer 104 may include one or more dielectric layers. The interposer 104 is coupled to the first package 102 through a first solder ball 150, a second solder ball 152, a third solder ball 154, and a fourth solder ball 156. For example, the second solder ball 152 is coupled to the pad 126 of the package substrate 122, and the pad 144 of the interposer 104.

A mass reflow process may be applied in order to couple the interposer 104 to the first package 102. During the mass reflow process, the interposer 104 is mounted, pressed, compressed, and/or cured (e.g., heated) or metallically joined on the first package 102 by raising the temperature of the assembly. During this mounting, pressing, compression, and/or curing operation, several things can happen which can lead to a failure of the device 100.

One, too much pressure can be applied on the interposer 104, causing the interposer 104 to either warp (e.g., bend, crack) and/or tilt on a certain side. As shown in FIG. 1, the interposer 104 is titled on the left hand side. Second, two or more of the solder balls that are used to couple the interposer 104 to the first package 102 may touch, resulting in a short of the device. As shown in FIG. 1, the first solder ball 150 is touching the second solder ball 152, resulting in a short of the device 100. Third, the joint (e.g., interface at which solder is coupled to an interconnect) may be weak. As shown in FIG. 1, the third solder ball 154 is barely touching the pad of the package substrate 122. A weak joint connection can result in poor and/or unreliable signal quality in the device 100. Fourth, there may be a lack of a mechanically continuous joint (i.e., there is an open joint) between the interposer 104 and the package substrate 122. An open joint is when there is no physical contact between two components. As shown in FIG. 1, the fourth solder ball 156 is coupled to the interposer 104, but not to the package substrate 122. Fifth, the warpage of the interposer 104 due to change in the temperatures (from heating and cooling) will cause open and shorts in the connection.

FIG. 2 illustrates another conventional device 200 that includes a first package 202 and the interposer 104. The first package 202 includes the first die 120 and the first package substrate 122. The first package substrate 122 includes the first set of pads 124 and the second set of pads 126, which includes pad 126. The first package substrate 122 may include one or more dielectric layers.

The device 200 is similar to the device 100, except that the device 200 uses a different connection to couple the interposer 104 to the first package 202. The first package 202 includes a first copper ball 250, a second copper ball 252, a third copper ball 254, a fourth copper ball 256, a first solder 260, a second solder 262, a third solder 264, and a fourth solder 266. The first solder 260 surrounds the first copper ball 250, the second solder 262 surrounds the second copper ball 252, the third solder 264 surrounds the third copper ball 254, and the fourth solder 266 surrounds the fourth copper ball 256. The copper balls 250, 252, 254, and 256 help minimize the likelihood of shorts occurring since copper balls are solid materials at the temperature where the solder surrounding the copper ball (e.g., solder balls 260, 262, 264, 266) becomes molten and forms a metallic bond with the interposer pad 144 and bottom substrate pad 126. As the copper balls are solid during interposer attach, they are less likely to be compressed than solder and prevent the interposer conductive interconnections from shorting to one another. However, the approach of FIG. 2 is more expensive than other approaches.

Therefore, there is a need for a device (e.g., package on package (PoP) device) with reliable joints to ensure better quality and/or performance signals between packages. Ideally, such a device will have a better form factor, be cheaper to fabricate, while at the same time meeting the needs and/or requirements of mobile and/or wearable devices.

### SUMMARY

Various features, apparatus and methods described herein an integrated device package that includes a heterogeneous solder joint structure.

A first example provides an integrated circuit device that includes a first package substrate, a first die coupled to the first package substrate, a second package substrate, and a solder joint structure coupled to the first package substrate and the second package substrate. The solder joint structure includes a solder comprising a first melting point temperature, and a conductive material comprising a second melting point temperature that is less than the first melting point temperature.

A second example provides a method for fabricating an integrated circuit device. The method provides a first package substrate. The method couples a first die to the first package substrate. The method provides a second package substrate. The method forms a solder joint structure on the first package substrate and the second package substrate. The forming of the solder joint structure includes forming a solder on the second package substrate. The solder includes a first melting point temperature. The forming of the solder joint structure includes coupling a conductive material to the solder. The conductive material includes a second melting point temperature that is less than the first melting point temperature.

A third example provides an integrated circuit device that includes a first package substrate, a first die coupled to the first package substrate, a second package substrate, a solder joint structure coupled to the first package substrate and the second package substrate. The solder joint structure includes a solder comprising a first melting point temperature, and a conductive material comprising a second solidification temperature that is less than the first melting point temperature.

### DRAWINGS

Various features, nature and advantages may become apparent from the detailed description set forth below when taken in conjunction with the drawings in which like reference characters identify correspondingly throughout.

FIG. 1 illustrates a conventional integrated device package.

FIG. 2 illustrates a conventional integrated device package.

FIG. 3 illustrates a package on package (PoP) device that includes a solder joint structure.

FIG. 4 illustrates another package on package (PoP) device that includes a solder joint structure.

FIG. 5 illustrates an exemplary sequence for providing/fabricating a package on package (PoP) device that includes a solder joint structure.

FIG. 6 illustrates an exemplary close up view of one of the stages of the sequence of FIG. 5.

FIG. 7 illustrates an exemplary close up view of one of the stages of the sequence of FIG. 5.

FIG. 8 illustrates another exemplary sequence for providing/fabricating a package on package (PoP) device that includes a solder joint structure.

FIG. 9 illustrates an exemplary flow diagram of a method for providing/fabricating a package on package (PoP) device that includes a solder joint structure.

FIG. 10 illustrates an exemplary sequence for providing/fabricating a package on package (PoP) device that includes a solder joint structure.

FIG. 11 illustrates an exemplary close up view of one of the stages of the sequence of FIG. 10.

FIG. 12 illustrates an exemplary close up view of one of the stages of the sequence of FIG. 10.

FIG. 13 illustrates an exemplary sequence for providing/fabricating a package on package (PoP) device that includes a solder joint structure.

FIG. 14 illustrates an exemplary flow diagram of a method for providing/fabricating a package on package (PoP) device that includes a solder joint structure.

FIG. 15 illustrates an exemplary solder joint structure.

FIG. 16 illustrates another exemplary solder joint structure.

FIG. 17 illustrates an exemplary solder joint structure.

FIG. 18 illustrates another exemplary solder joint structure.

FIG. 19 illustrates an exemplary solder joint structure.

FIG. 20 illustrates another exemplary solder joint structure.

FIG. 21 illustrates an example of a semi-additive patterning (SAP) process.

FIG. 22 illustrates an example of flow diagram of a semi-additive patterning (SAP) process.

FIG. 23 illustrates an example of a damascene process.

FIG. 24 illustrates an example of a flow diagram of a damascene process.

FIG. 25 illustrates various electronic devices that may integrate an integrated device, an integrated device package, a semiconductor device, a die, an integrated circuit, a substrate, an interposer, a package-on-package device, and/or PCB described herein.

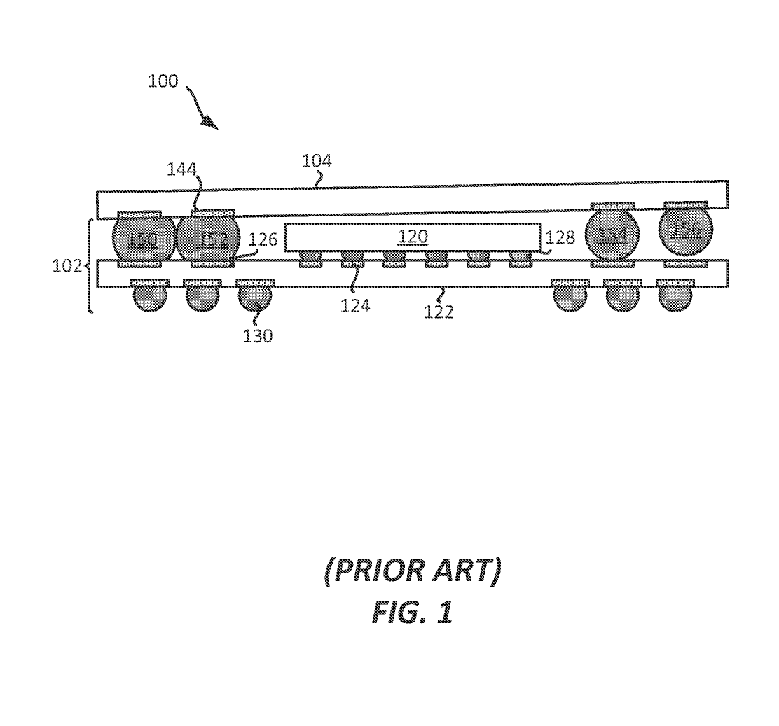

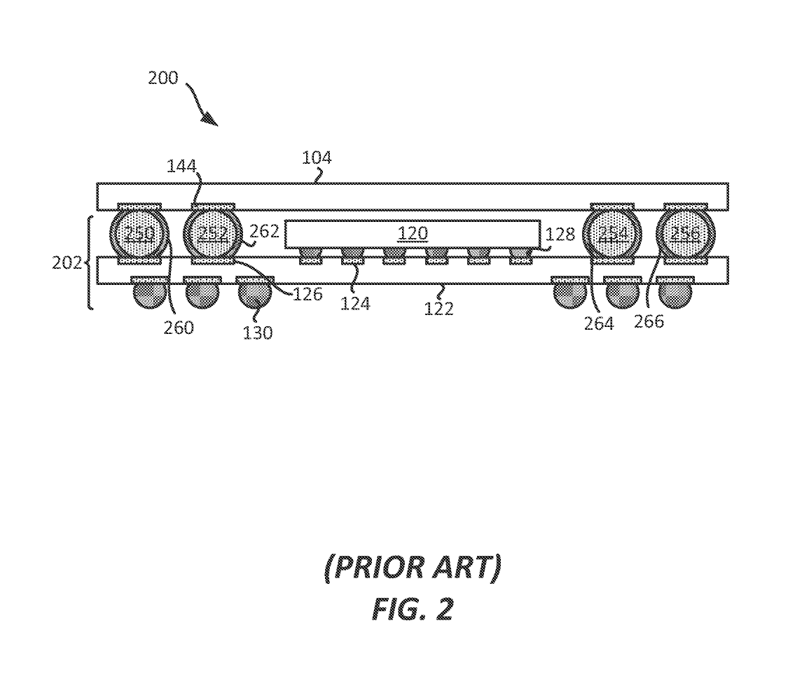

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some features pertain to an integrated device package (e.g., integrated circuit device) that includes a first package substrate, a first die (e.g., first integrated circuit) coupled to the first package substrate, a solder joint structure coupled to the first package substrate, and a second package substrate coupled to the solder joint structure. The solder joint structure includes a solder and a conductive material. The solder has a first melting point temperature. The conductive material has a second property temperature (e.g., melting point temperature, curing temperature, solidification temperature) that is less than the first melting point temperature of the solder. In some implementations, the conductive material is one of at least a homogeneous material and/or a heterogeneous material. In some implementations, the conductive material includes a first electrically conductive material and a second material. The conductive material is an electrically conductive material. The first package substrate includes a first pad, and the second package substrate includes a second pad. The solder joint structure is coupled to the first pad and the second pad. In some implementations, the integrated device package includes a layer between the first die and the second package substrate. The layer may be an adhesive layer.

In some implementation, an interconnect is an element or component of a device (e.g., integrated device, integrated device package, die) and/or a base (e.g., package substrate, printed circuit board, interposer) that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect is an electrically conductive material that provides an electrical path for a signal (e.g., data signal, ground signal, power signal). An interconnect may include more than one element/component.

### Exemplary Integrated Device Package Comprising Solder Joint Structure

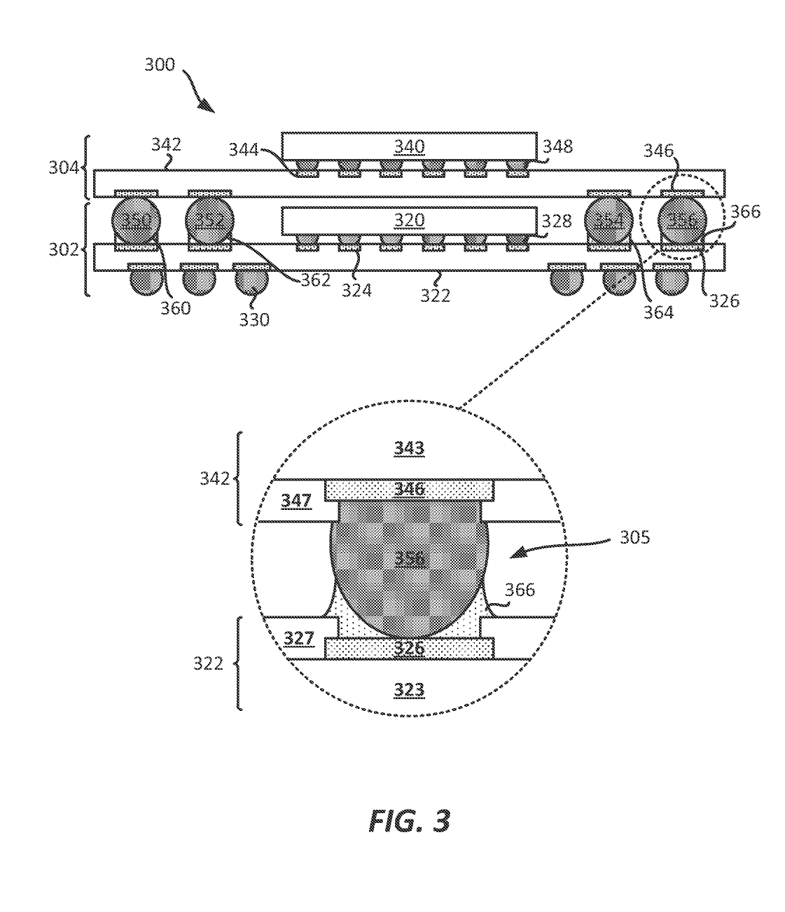

FIG. 3 illustrates a package on package (PoP) device 300 that includes a solder joint structure. The PoP device 300 includes a first package 302 (e.g., integrated package), a second package 304, and a solder joint structure 305. The first package 302 is coupled to the second package 304 through at least one solder joint structure 305. The PoP device 300 may include several solder joint structures 305. The first package 302 includes a first die 320 and a first package substrate 322. The second package 304 (e.g., integrated package) includes a second die 340 and a second package substrate 342. A die (e.g., first die 320, second die 340) may be an integrated circuit (IC) that includes several transistors and/or other electronic components. A package or an integrated package may be an integrated circuit device that includes an integrated circuit (IC).

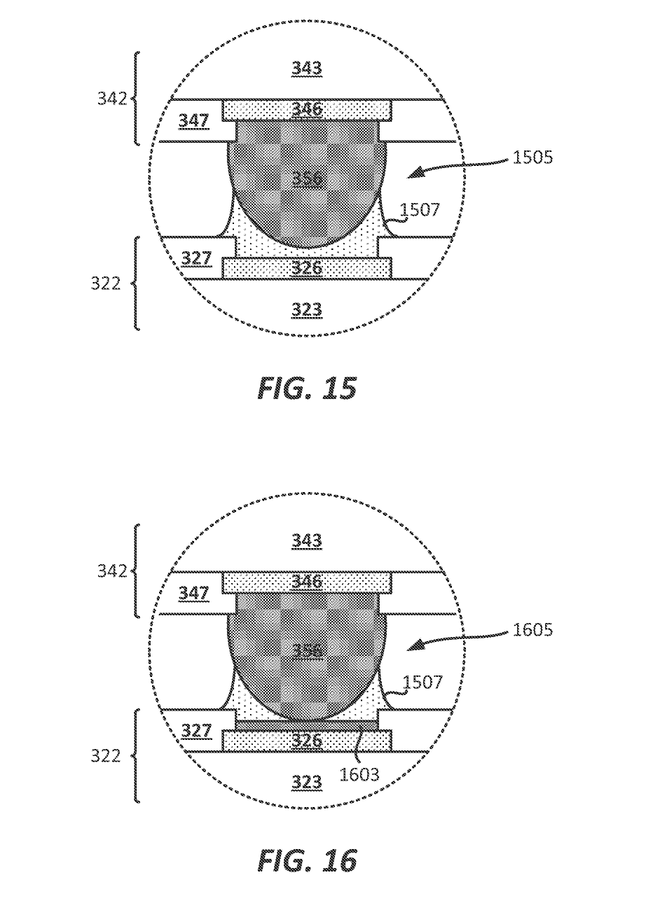

The first package substrate 322 includes a first set of pads 324 and a pad 326 (e.g., pad from a second set of pads). The first package substrate 322 may include one or more dielectric layers (e.g., dielectric layer 323). The first package substrate 322 includes a first solder resist layer 327. The first solder resist layer 327 is on the dielectric layer 323. The first die 320 is coupled to the first package substrate 322 through a first set of solder balls 328. Specifically, the first die 320 is coupled to the first set of pads 324 through the first set of solder balls 328. A second set of solder balls 330 is coupled to the first package substrate 322. It should be noted that the solder resist layer 327 is optional. In some implementations, other layers may be used on the dielectric layer 323. For example, a dielectric layer, an encapsulation layer (e.g., mold compound), and/or a polymer may be formed on the dielectric layer 323 and/or the solder resist layer 327. Examples of different materials are further described below in at least FIGS. 15-20.

The second package substrate 342 includes a third set of pads 344 and a pad 346 (e.g., pad from a fourth set of pads). The second package substrate 342 may include one or more dielectric layers (e.g., dielectric layer 343). The second package substrate 342 includes a second solder resist layer 347. The second solder resist layer 347 is on the dielectric layer 343. The second package substrate 342 may be an interposer. The second die 340 is coupled to the second package substrate 342 through a third set of solder balls 348. Specifically, the second die 340 is coupled to the third set of pads 344 through the third set of solder balls 348.

As mentioned above, the PoP device 300 may include several solder joint structures (e.g., solder joint structure 305) that couple the first package substrate 322 to the second package substrate 342. In some implementations a solder joint structure may include a solder ball (e.g., solder ball 356) and a conductive material (e.g., conductive material 366). For example, the pad 346 of the second package substrate 342 may be coupled to the pad 326 of the first package substrate 322 through the solder joint structure 305 that includes the solder ball 356 and the conductive material 366. In some implementations, the pitch of several solder joint structures is about 270 microns (μm) or less. In some implementations, the pitch of several solder joint structures is about 200 microns (μm) or less. In some implementations, the pitch of several solder joint structures is about 100 microns (μm) or less.

As further shown in FIG. 3, the second package substrate 342 is coupled to the first package substrate 322 through a first solder ball 350, a first conductive material 360, a second solder ball 352, a second conductive material 362, a third solder ball 354, a third conductive material 364, a fourth solder ball 356, and a fourth conductive material 366. For example, the fourth solder ball 356 is coupled to the pad 326 of the first package substrate 322, and the pad 346 of the second package substrate 342. The fourth solder ball 356 is also coupled to the fourth conductive material 366. The fourth conductive material 366 is coupled to the pad 326. The pad 326 and/or the pad 346 may be surface pads or embedded pads. For example, the pad 326 may be embedded in the dielectric layer 323.

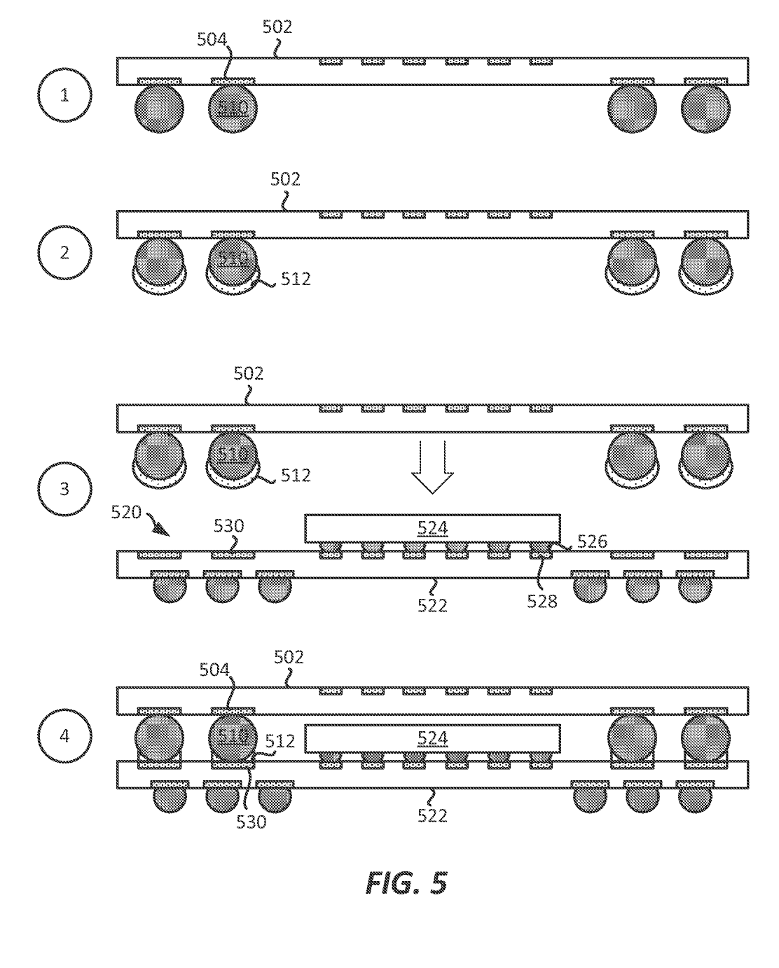

The first, second, third, and fourth conductive materials 360, 362, 364, and 366 are an electrically conductive material that is made of a different material than the solder balls 350, 352, 354, and 356. In some implementations, the solder balls 350, 352, 354, and 356 have a first temperature property (e.g., first melting point temperature) than a temperature property (e.g. second melting point temperature, curing temperature, solidification temperature) of the conductive materials 360, 362, 364, and 366. For example, the solder ball may have a melting point temperature of about 220 Celsius, while the conductive material 366 has a melting point temperature, curing temperature, and/or solidification temperature that is less than about 220 Celsius. As will be further described in FIGS. 5, 8, 10 and 13, the melting points temperature of the solder ball and the melting point temperature, curing temperature, and/or solidification temperature of the conductive material may play an important part in the fabrication of a device that includes a first substrate coupled to a second substrate. In some implementations, the conductive material 366 may have a melting point temperature that is greater than a heating temperature during a lead free solder reflow process.

In some implementations, a melting point temperature of a material is a temperature at which the material begins to melt (e.g., beings to melt from a solid state). In some implementations, a curing temperature of a material is a temperature at which the material begins to cure. In some implementations, a solidification temperature of a material is a temperature at which the material begins to solidify (e.g., begins to solidify from a non-solid state, begins to solidify from a liquid state).

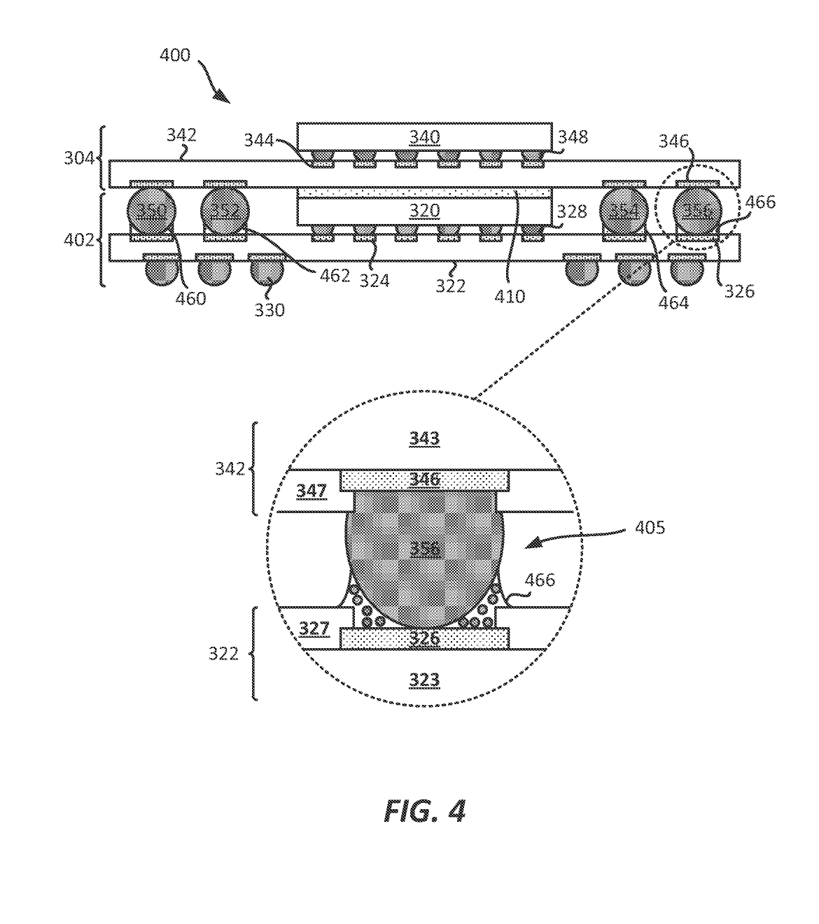

Different implementations may use different electrically conductive materials. In some implementations, the conductive material (e.g., conductive material 360) may include a material that is viscous before the material is cured and/or solidified (e.g., solidified after being heated). In some implementations, a viscous material is a material that is between a solid state and a liquid state. The conductive material may be homogeneous or heterogeneous. In some implementations, the conductive material may include a heterogeneous material that includes at least two materials. An example of a heterogeneous material is illustrated and described in FIG. 4.

In some implementations, the use of the combination of solder ball (e.g., solder ball 356) and the conductive material (e.g., conductive material 366) provides a reliable joint structure between the first package substrate 322 and the second package substrate 342. In some implementations, the solder ball (e.g., solder ball 356) acts as mechanical stop that prevents the second package substrate 342 from overly compressing onto the first package 302. In addition, the conductive material (e.g., conductive material 366) may fill up a gap between the solder ball (e.g., solder ball 356) and the pad (e.g., pad 326), ensuring a strong joint. This in turn, reduces the likelihood of shorting between solder balls, and provides reliable and solid joints between the first package substrate 322 and the second package substrate 342.

### Exemplary Integrated Device Package Comprising Solder Joint Structure

FIG. 4 illustrates another package on package (PoP) device 400 that includes a solder joint structure. The PoP device 400 includes a first package 402 (e.g., integrated circuit device), the second package 304, and a solder joint structure 405. The first package 402 is coupled to the second package 304 through at least one solder joint structure 405. The PoP device 400 may include several solder joint structures 405. The first package 402 includes the first die 320, the first package substrate 322, and a layer 410. The second package 304 (e.g., integrated circuit device) includes the second die 340 and the second package substrate 342. A die (e.g., first die 320, second die 340) may be an integrated circuit (IC) that includes several transistors and/or other electronic components. A package or an integrated package may be an integrated circuit device that includes an integrated circuit (IC).

As previously described above, the first package substrate 322 includes the first set of pads 324 and the pad 326 (e.g., from a second set of pads). The first package substrate 322 may include one or more dielectric layers (e.g., dielectric layer 323). The first package substrate 322 includes the first solder resist layer 327. The first solder resist layer 327 is on the dielectric layer 323. The first die 320 is coupled to the first package substrate 322 through the first set of solder balls 328. Specifically, the first die 320 is coupled to the first set of pads 324 through the first set of solder balls 328. The second set of solder balls 330 is coupled to the first package substrate 322.

As described above, the second package substrate 342 includes the third set of pads 344 and the pad 346 (e.g., the fourth set of pads). The second package substrate 342 may include one or more dielectric layers (e.g., dielectric layer 343). The second package substrate 342 includes the second solder resist layer 347. The second solder resist layer 347 is on the dielectric layer 343. The second package substrate 342 may be an interposer. The second die 340 is coupled to the second package substrate 342 through a third set of solder balls 348. Specifically, the second die 340 is coupled to the third set of pads 344 through the third set of solder balls 348.

As shown in FIG. 4, the layer 410 is located between the first package 402 and the second package 304. Specifically, the layer 410 is located between the die 320 and the second package substrate 342. In some implementations, the layer 410 is an adhesive layer or adhesive material that is coupled to the die 320. The layer 410 may be coupled to the second package substrate 342. In some implementations, the layer 410 may be adapted or configured to operate as mechanical stop when the package substrate 342 is mounted or coupled to the first package 402. The layer 410 may be used to ensure that the second package 304 and/or the second package substrate 342 does not overly compress the solder balls onto the first package 302. This in turn, reduces the likelihood of shorting between solder balls, and provides reliable and solid joints between the first package substrate 322 and the second package substrate 342. In some implementations, when the layer 410 is used, the solder ball 356 may not be in direct physical contact with the pad 326. In such instances, the solder ball 356 may be coupled (e.g., electrically coupled) to the pad 326 through the conductive material 466. Examples of when a solder ball is not in direct contact with a pad are further described below in at least FIGS. 15-20.

As mentioned above, the PoP device 400 may include several solder joint structures (e.g., solder joint structure 405) that couple the first package substrate 322 to the second package substrate 342. In some implementations a solder joint structure may include a solder ball (e.g., solder ball 456) and a conductive material (e.g., conductive material 466). For example, the pad 346 of the second package substrate 342 may be coupled to the pad 326 of the first package substrate 322 through the solder joint structure 405 that includes the solder ball 456 and the conductive material 466.

As further shown in FIG. 4, the second package substrate 342 is coupled to the first package substrate 322 through a first solder ball 350, a first conductive material 460, a second solder ball 352, a second conductive material 462, a third solder ball 354, a third conductive material 464, a fourth solder ball 356, and a fourth conductive material 466. For example, the fourth solder ball 356 is coupled to the pad 326 of the first package substrate 322, and the pad 346 of the second package substrate 342. The fourth solder ball 356 is also coupled to the fourth conductive material 466. The fourth conductive material 366 is coupled to the pad 326.

The first, second, third, and fourth conductive materials 460, 462, 464, and 466 are an electrically conductive material that is made of a different material than the solder balls 350, 352, 354, and 356. In some implementations, the solder balls 350, 352, 354, and 356 have a first property (e.g., first melting point temperature) than a property (e.g. second melting point temperature, curing temperature, solidification temperature) of the conductive materials 460, 462, 464, and 466. For example, the solder ball may have a melting point temperature of about 220 Celsius, while the conductive material 466 has a melting point temperature, solidification temperature, and/or curing temperature that is less than about 220 Celsius. In some implementations, the conductive material 466 may have a melting point temperature that is greater than a heating temperature during a lead free solder reflow process.

Different implementations may use different electrically conductive materials. In some implementations, the conductive material (e.g., conductive material 460) may include a material that is viscous before the material is cured and/or solidified (e.g., solidified after being heated). In some implementations, a viscous material is a material that is between a solid state and a liquid state. The conductive material may be homogeneous or heterogeneous. In some implementations, the conductive material may include a heterogeneous material that includes at least two materials. For example, the heterogeneous material may include a first electrically conductive material and a second electrically conductive material (e.g., small conductive fills, beads or pellets). In another example, the heterogeneous material may includes a first non-electrically conductive material and a second electrically conductive material. An example of the heterogeneous material would be an electrically conductive polymer with metallic filler particles such as copper, aluminum, or silver. An example of a non-electrically conductive material would be an epoxy polymer matrix with metallic conductive particles. Another example of a material would be a transient liquid phase sintering composite may be used where the composite comprises a viscous curable polymeric carrier matrix and a combination of electrically filler of which at least one material becomes liquid at a temperature lower than the melting temperature of the solder and thereupon reacts with the conductive filler particles in the composite material and with the solder ball and also with the pad 326 to form a metallic interconnection between the pad 326, filler particles in the heterogeneous conductive material 466, and to the solder ball 356 attached to the first package substrate 322.

In some implementations, the use of the combination of solder ball (e.g., solder ball 356) and the conductive material (e.g., conductive material 466) provides a reliable joint structure between the first package substrate 322 and the second package substrate 342. In some implementations, the solder ball (e.g., solder ball 456) acts as mechanical stop that prevents the second package substrate 342 from overly compressing onto the first package 302. In addition, the conductive material (e.g., conductive material 466) may fill up a gap between the solder ball (e.g., solder ball 356) and the pad (e.g., pad 326), ensuring a strong joint. This in turn, increases the likelihood of forming an electrically continuous joint and reduces the likelihood of shorting between solder balls, and provides reliable and solid joints between the first package substrate 322 and the second package substrate 342.

Having described several integrated device packages comprising a solder joint structure, a method for providing and/or fabricating such an integrated device package that includes a solder joint structure will now be described below.

### Exemplary Sequence for Providing/Fabricating an Integrated Device Package Comprising Solder Joint Structure

In some implementations, providing/fabricating an integrated device package (e.g., integrated circuit device) that includes a solder joint structure includes several processes. FIG. 5 illustrates an exemplary sequence for providing/fabricating an integrated device package that includes a solder joint structure. In some implementations, the sequence of FIG. 5 may be used to provide/fabricate the integrated device packages of FIGS. 3-4 and/or other integrated device packages described in the present disclosure. However, for the purpose of simplification, FIG. 5 will be described in the context of providing/fabricating the integrated device package of FIG. 3.

It should be noted that the sequence of FIG. 5 may combine one or more stages in order to simplify and/or clarify the sequence for providing an integrated device package (e.g., integrated circuit device). In some implementations, the order of the processes may be changed or modified.

Stage 1 illustrates a state after a substrate 502 is provided. The substrate 502 may be an interposer. The substrate 502 may be a package substrate of an integrated device package. In some implementations, the substrate 502 is the second package substrate 342 of FIG. 3. The substrate 502 includes one or more dielectric layers (e.g., dielectric layer 343), at least one pad 504, and a solder resist layer (e.g., solder resist layer 347). The substrate 502 is coupled to at least one solder ball (e.g., solder ball 510).

Stage 2 illustrates a state after a conductive material 512 is provided on the solder ball 510. Different implementations may provide the conductive material 512 on the solder ball 510 differently. For example, the solder ball 510 may be dipped in the conductive material 512 by motion into and out of a material reservoir (not shown). The conductive material 512 may also be applied by a brushing process, a stamping process, a dispensing process, a spraying process, a printing process or other techniques that transfer the conductive material 512 to the solder ball 510. In some implementations, the conductive material 512 is an electrically conductive material. Different implementations may use different materials for the conductive material 512. The conductive material may be homogeneous or heterogeneous. In some implementations, the conductive material may include a material that is viscous before the material is cured and/or solidified (e.g., solidified after being heated). In some implementations, a viscous material is a material that is between a solid state and a liquid state. In some implementations, the conductive material may include a heterogeneous material that includes at least two materials. For example, the heterogeneous material may include a first electrically conductive material and a second electrically conductive material (e.g., small conductive fills, beads or pellets). In another example, the heterogeneous material may includes a first non-electrically conductive material and a second electrically conductive material. In some implementations, the conductive material 512 has a lower melting point temperature, curing temperature and/or solidification temperature than the melting point temperature of the solder ball 510.

Stage 3 illustrates a state as the substrate 502 is mounted to the integrated device package 520. The integrated device package 520 includes a first package substrate 522 and a die 524. In some implementations, the first package substrate 522 is the package substrate 322 of FIG. 3. The first package substrate 522 includes a first set of pads 528 and a second set of pads 530. The first package substrate 522 may include one or more dielectric layers (e.g., dielectric layer 323) and the first solder resist layer 327. The first die 524 is coupled to the first package substrate 522 through a first set of solder balls 526. Specifically, the first die 524 is coupled to the first set of pads 528 through the first set of solder balls 526.

Stage 4 illustrates a state after the substrate 502 is coupled to the first package substrate 522. At least one solder joint structure is formed between the substrate 502 and the first package substrate 522. The solder joint structure may include the solder ball 510 and the conductive material 512.

In some implementations, stage 4 illustrates a state after the solder joint structure has been cured and/or solidified (e.g., heated and solidified). In some implementations, the solder joint structure is cured and/or solidified using a temperature that is less than the melting point temperature (e.g., less than about 220 Celsius) of the solder ball 510. In such an instances, the solder ball 510 remains a solid and acts a mechanical stop, while the conductive material 512 coats, wets and fills voids and/or cavities that may exist between the solder ball 510 and the pad 530. This process ensures a solid and reliable joint between the two substrates.

In some implementations, solidification is a change of state from a liquid state (or viscous state) to a solid state/material. For example, when a solder transitions from a liquid volume to a solid volume this is solidification. In another example, the metallic components of a transient liquid phase sintering material would also solidify as the material includes two metal components, one of which melts at a relatively low temperature. However, the low melting point material rapidly wets to both the filler particles and conductive metal pads on the substrate and solidifies.

In some implementations, curing is the process of a polymeric material cross-linking, commonly initiated by thermal energy, and is a process by which prepolymers contained within the viscous paste form a polymeric network. A conductive adhesive cures into a solid or an elastomeric material around the filler contained within the conductive material and/or adhesive. For example, the polymeric material surrounding the transient liquid phase metallic filler particles will also cure. In some implementations, when the conductive material starts out as a viscous paste and cures, then it has solidified.

In some implementations, a second die (e.g., die 340) may be placed on the substrate 502 before, during, or after stage 4.

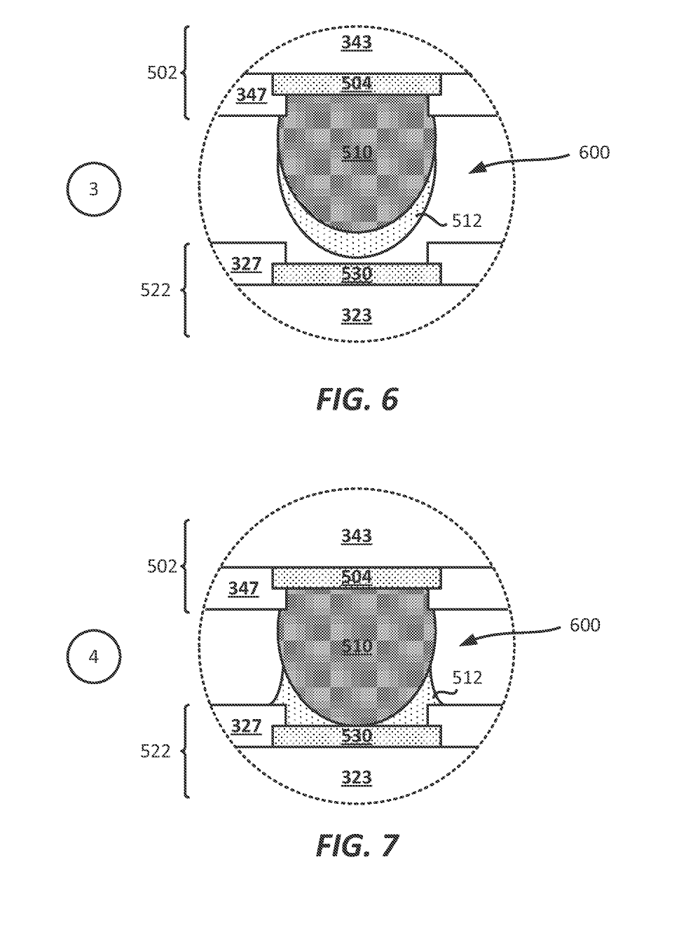

FIG. 6 and FIG. 7 respectively illustrate close up views of the solder joint structure of stages 3 and 4 of FIG. 5. Specifically, FIG. 6 illustrates a close up view of the substrate 502 being mounted on the package substrate 522 during stage 3 of FIG. 5. The substrate 502 includes the dielectric layer 343, the solder resist layer 347, and the pad 504. A solder joint structure 600 is coupled to the pad 504. The solder joint structure 600 includes the solder ball 510 and the conductive material 512. The solder ball 510 is coupled to the pad 504. The package substrate 522 includes the dielectric layer 323, the solder resist layer 327, and the pad 530.

FIG. 7 illustrates a close up view after the substrate 502 is coupled to the package substrate 522 during stage 4 of FIG. 5. As shown in FIG. 7, the solder joint structure 600 is coupled to the pad 504 and the pad 530. The solder ball 510 may be adapted or configured as a mechanical stop during the mounting of the substrate 502 to the package substrate 522.

### Exemplary Sequence for Providing/Fabricating an Integrated Device Package Comprising Solder Joint Structure

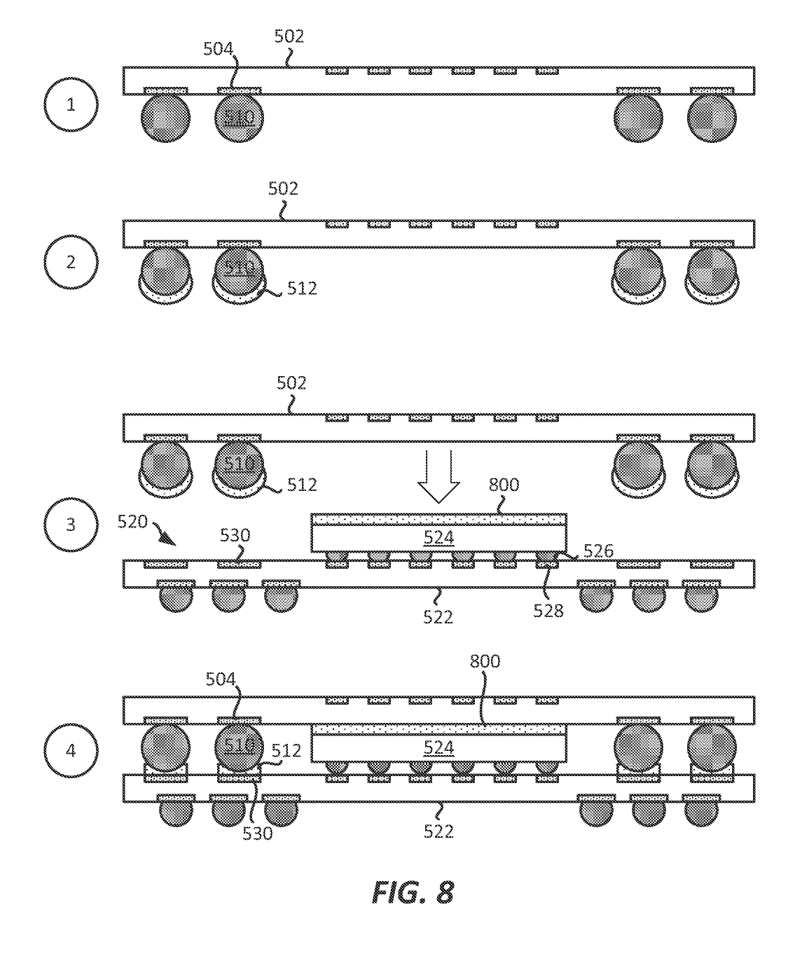

In some implementations, providing/fabricating an integrated device package (e.g., integrated circuit device) that includes a solder joint structure includes several processes. FIG. 8 illustrates an exemplary sequence for providing/fabricating an integrated device package that includes a solder joint structure. In some implementations, the sequence of FIG. 8 may be used to provide/fabricate the integrated device packages of FIGS. 3-4 and/or other integrated device packages described in the present disclosure. However, for the purpose of simplification, FIG. 8 will be described in the context of providing/fabricating the integrated device package of FIG. 4.

It should be noted that the sequence of FIG. 8 may combine one or more stages in order to simplify and/or clarify the sequence for providing an integrated device package (e.g., integrated circuit device). In some implementations, the order of the processes may be changed or modified.

Stage 1 illustrates a state after a substrate 502 is provided. The substrate 502 may be an interposer. The substrate 502 may be a package substrate of an integrated device package. In some implementations, the substrate 502 is the second package substrate 342 of FIG. 3. The substrate 502 includes one or more dielectric layers (e.g., dielectric layer 343), at least one pad 504, and a solder resist layer (e.g., solder resist layer 347). The substrate 502 is coupled to at least one solder ball (e.g., solder ball 510).

Stage 2 illustrates a state after a conductive material 512 is provided on the solder ball 510. Different implementations may provide the conductive material 512 on the solder ball 510 differently. For example, the solder ball 510 may be dipped in the conductive material 512 (e.g., conductive material dispense). In some implementations, the conductive material 512 is an electrically conductive material. Different implementations may use different materials for the conductive material 512. The conductive material may be homogeneous or heterogeneous. In some implementations, the conductive material may include a material that is viscous before the material is cured and/or solidified (e.g., solidified after being heated). In some implementations, a viscous material is a material that is between a solid state and a liquid state. In some implementations, the conductive material may include a heterogeneous material that includes at least two materials. For example, the heterogeneous material may include a first electrically conductive material and a second electrically conductive material (e.g., small conductive fills, beads or pellets). In another example, the heterogeneous material may includes a first non-electrically conductive material and a second electrically conductive material. In some implementations, the conductive material 512 has a lower melting point temperature, a curing temperature, and/or solidification temperature than the melting point temperature of the solder ball 510.

Stage 3 illustrates a state as the substrate 502 is mounted to the integrated device package 520. The integrated device package 520 includes a first package substrate 522 and a die 524. In some implementations, the first package substrate 522 is the package substrate 322 of FIG. 3. The first package substrate 522 includes a first set of pads 528 and a second set of pads 530. The first package substrate 522 may include one or more dielectric layers (e.g., dielectric layer 323) and the first solder resist layer 327. The first die 524 is coupled to the first package substrate 522 through a first set of solder balls 526. Specifically, the first die 524 is coupled to the first set of pads 528 through the first set of solder balls 526.

Stage 3 also illustrates a layer 800 located on the die 524. In some implementations, the layer 800 is an adhesive layer or adhesive material that is coupled to the die 524. In some implementations, the layer 800 may be adapted or configured to operate as mechanical stop when the package substrate 502 is mounted or coupled to the integrated device package 520. The layer 800 may be used to ensure that the substrate 502 does not overly compress the solder balls onto the integrated device package 520.

Stage 4 illustrates a state after the substrate 502 is coupled to the first package substrate 522. At least one solder joint structure is formed between the substrate 502 and the first package substrate 522. The solder joint structure may include the solder ball 510 and the conductive material 512. The layer 800 is located between the die 524 and the substrate 502.

In some implementations, stage 4 illustrates a state after the solder joint structure has been cured and/or solidified (e.g., heated and solidified). In some implementations, the solder joint structure is cured and/or solidified using a temperature that is less than the melting point temperature (e.g., less than about 220 Celsius) of the solder ball 510, but higher than the melting point temperature, curing temperature and/or solidification temperature of the conductive material 512. In such an instances, the solder ball 510 remains a solid and acts a mechanical stop, while the conductive material 512 coats, wets and fills voids and/or cavities that may exist between the solder ball 510 and the pad 530. This process ensures a solid and reliable joint between the two substrates.

In some implementations, a second die (e.g., die 340) may be placed on the substrate 502 before, during, or after stage 4.

### Exemplary Method for Providing/Fabricating an Integrated Device Package Comprising Solder Joint Structure

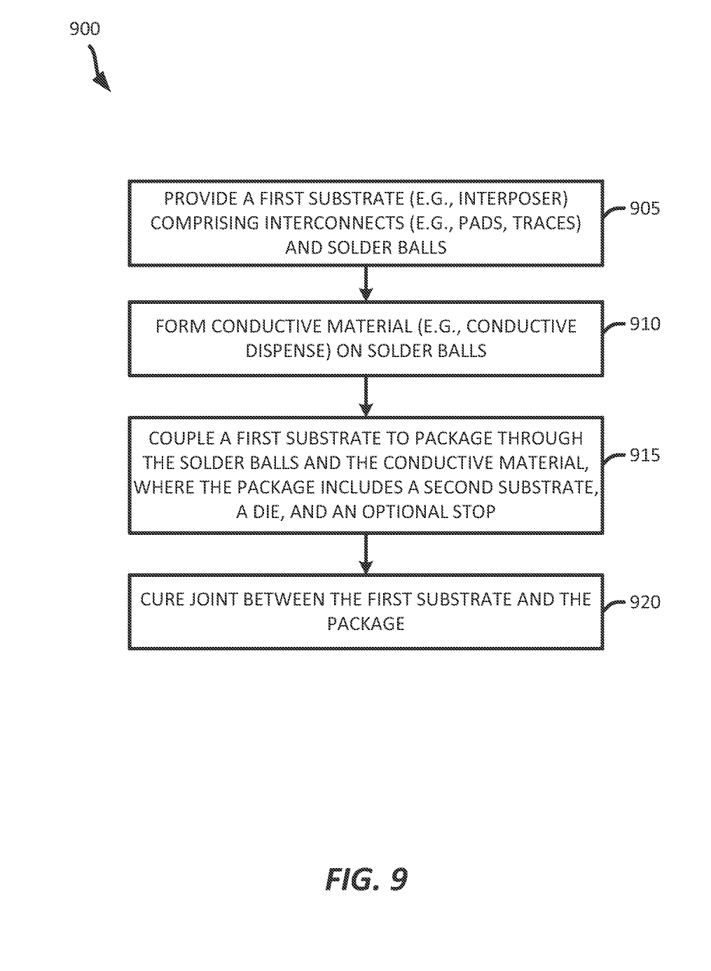

FIG. 9 illustrates an exemplary flow diagram of a method 900 for providing/fabricating an integrated device package (e.g., integrated circuit device) that includes a solder joint structure. In some implementations, the method of FIG. 9 may be used to provide/fabricate the integrated device package (e.g., integrated circuit device) that includes a solder joint structure of FIGS. 3-4.

It should be noted that the flow diagram of FIG. 9 may combine one or more step and/or processes in order to simplify and/or clarify the method for providing an integrated device package (e.g., integrated circuit device). In some implementations, the order of the processes may be changed or modified.

The method provides (at 905) a substrate. The substrate may be an interposer. The substrate may be a package substrate of an integrated device package. In some implementations, the substrate is the package substrate 342 of FIG. 3. The substrate includes one or more dielectric layers (e.g., dielectric layer 343), at least one pad (e.g., pad 504), and a solder resist layer (e.g., solder resist layer 347). The substrate is coupled to at least one solder ball (e.g., solder ball 510).

The method forms (at 910) a conductive material on the solder ball. Different implementations may form the conductive material on the solder ball differently. For example, the solder ball may be dipped in the conductive material (e.g., conductive material dispense). In some implementations, the conductive material is an electrically conductive material. Different implementations may use different materials for the conductive material. The conductive material may be homogeneous or heterogeneous. In some implementations, the conductive material may include a material that is viscous before the material is cured and/or solidified (e.g., solidified after being heated). In some implementations, a viscous material is a material that is between a solid state and a liquid state. In some implementations, the conductive material may include a heterogeneous material that includes at least two materials. For example, the heterogeneous material may include a first electrically conductive material and a second electrically conductive material (e.g., small conductive fills, beads or pellets). In another example, the heterogeneous material may includes a first non-electrically conductive material and a second electrically conductive material. In some implementations, the conductive material has a lower melting point temperature, curing temperature, and/or solidification temperature than the melting point temperature of the solder ball.

The method couples (at 915) the substrate to the integrated device package through at least one solder joint structure, where the solder joint structure includes a solder ball and a conductive material. The integrated device package includes a first package substrate and a die. In some implementations, the first package substrate 522 is the package substrate 322 of FIG. 3. The first package substrate includes a first set of pads and a second set of pads. The first package substrate may include one or more dielectric layers (e.g., dielectric layer 323) and a first solder resist layer. The first die is coupled to the first package substrate through a first set of solder balls. Specifically, the first die is coupled to the first set of pads through the first set of solder balls. In some implementations, a layer is located on the die. In some implementations, the layer is an adhesive layer or adhesive material that is coupled to the die. In some implementations, the layer may be adapted or configured to operate as mechanical stop when the package substrate is mounted or coupled to the integrated device package. The layer may be used to ensure that the substrate does not overly compress the solder balls onto the integrated device package.

The method cures and/or solidifies (at 920) the solder joint structure between the first substrate and the second substrate. In some implementations, the solder joint structure is cured and/or solidified using a temperature that is less than the melting point temperature (e.g., less than about 220 Celsius) of the solder ball, but higher than the melting point temperature, curing temperature, and/or solidification temperature of the conductive material. In such an instances, the solder ball remains a solid and acts a mechanical stop, while the conductive material coats, wets and fills voids and/or cavities that may exist between the solder ball and the pad of the package substrate.

In some implementations, the use of the conductive material bypasses the use (e.g., does not require the use) of a solder reflow process and/or flux cleaning process, thereby reducing the cost of fabricating/manufacturing the device.

### Exemplary Sequence for Providing/Fabricating an Integrated Device Package Comprising Solder Joint Structure

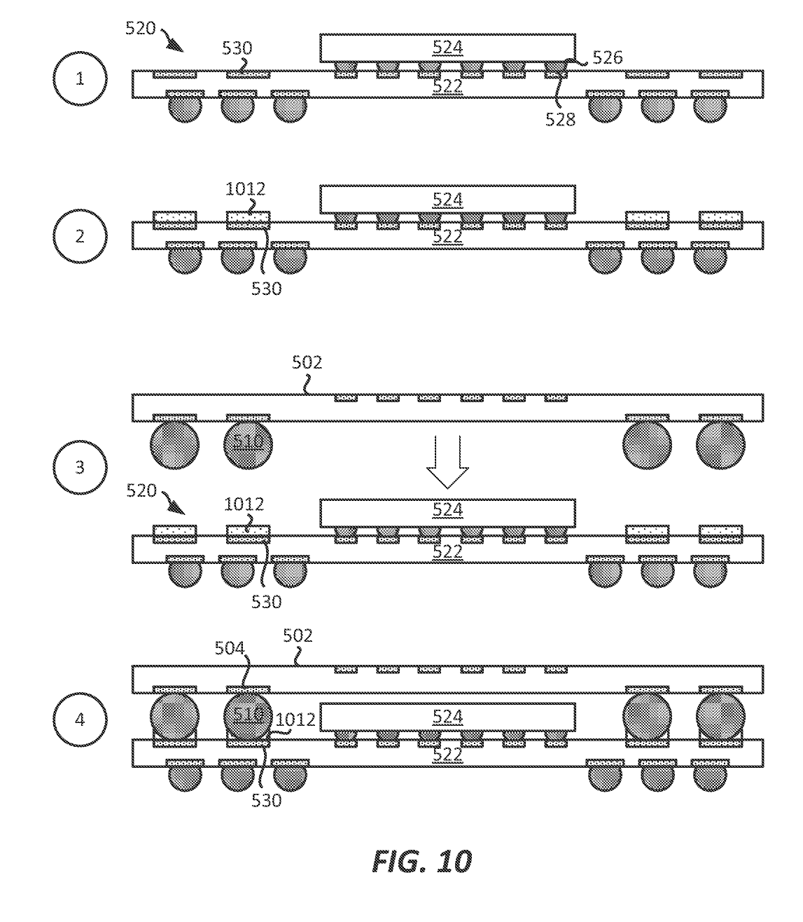

In some implementations, providing/fabricating an integrated device package (e.g., integrated circuit device) that includes a solder joint structure includes several processes. FIG. 10 illustrates an exemplary sequence for providing/fabricating an integrated device package (e.g., integrated circuit device) that includes a solder joint structure. In some implementations, the sequence of FIG. 10 may be used to provide/fabricate the integrated device packages of FIGS. 3-4 and/or other integrated device packages described in the present disclosure. However, for the purpose of simplification, FIG. 10 will be described in the context of providing/fabricating the integrated device package (e.g., integrated circuit device) of FIG. 3.

It should be noted that the sequence of FIG. 10 may combine one or more stages in order to simplify and/or clarify the sequence for providing an integrated device package (e.g., integrated circuit device). In some implementations, the order of the processes may be changed or modified.

Stage 1 illustrates a state after an integrated device package 520 is provided. The integrated device package 520 includes a first package substrate 522 and a die 524. In some implementations, the first package substrate 522 is the package substrate 322 of FIG. 3. The first package substrate 522 includes a first set of pads 528 and a second set of pads 530. The first package substrate 522 may include one or more dielectric layers (e.g., dielectric layer 323) and the first solder resist layer 327. The first die 524 is coupled to the first package substrate 522 through a first set of solder balls 526. Specifically, the first die 524 is coupled to the first set of pads 528 through the first set of solder balls 526.

Stage 2 illustrates after a conductive material 1012 is provided (e.g., formed) on at least pad 530. Different implementations may provide the conductive material 1012 on the pad 530 differently. For example, the conductive material may be deposited on the pad 530 using a variety of processes (e.g., a printing process, a stamping process, a dispensing process, a transferring process). In some implementations, the conductive material 1012 is an electrically conductive material. Different implementations may use different materials for the conductive material 1012. The conductive material may be homogeneous or heterogeneous. In some implementations, the conductive material may include a material that is viscous before the material is cured and/or solidified (e.g., solidified after being heated). In some implementations, a viscous material is a material that is between a solid state and a liquid state. In some implementations, the conductive material may include a heterogeneous material that includes at least two materials. For example, the heterogeneous material may include a first electrically conductive material and a second electrically conductive material (e.g., small conductive fills, beads or pellets). In another example, the heterogeneous material may includes a first non-electrically conductive material and a second electrically conductive material. In some implementations, the conductive material 1012 has a lower melting point temperature, curing temperature, and/or solidification temperature than the melting point temperature of a solder ball. In some implementations, the conductive material 1012 is a viscous, paste-like material, so before curing/solidification, the conductive material 1012 may flow when stress is applied but the conductive material 1012 will not completely self-level and in large retains its form when the stress is removed.

Stage 3 illustrates a state as the substrate 502 is mounted to the integrated device package 520. The substrate 502 may be an interposer. The substrate 502 may be a package substrate of an integrated device package. In some implementations, the substrate 502 is the second package substrate 342 of FIG. 3. The substrate 502 includes one or more dielectric layers (e.g., dielectric layer 343), at least one pad 504, and a solder resist layer (e.g., solder resist layer 347). The substrate 502 is coupled to at least one solder ball (e.g., solder ball 510).

Stage 4 illustrates a state after the substrate 502 is coupled to the first package substrate 522. At least one solder joint structure is formed between the substrate 502 and the first package substrate 522. The solder joint structure may include the solder ball 510 and the conductive material 512.

In some implementations, stage 4 illustrates a state after the solder joint structure has been cured and/or solidified (e.g., heated and solidified). In some implementations, the solder joint structure is cured and/or solidified using a temperature that is less than the melting point temperature (e.g., less than about 220 Celsius) of the solder ball 510. In such an instances, the solder ball 510 remains a solid and acts a mechanical stop, while the conductive material 512 coats, wets and fills voids and/or cavities that may exist between the solder ball 510 and the pad 530. This process ensures a solid and reliable joint between the two substrates.

In some implementations, a second die (e.g., die 340) may be placed on the substrate 502 before, during, or after stage 4.

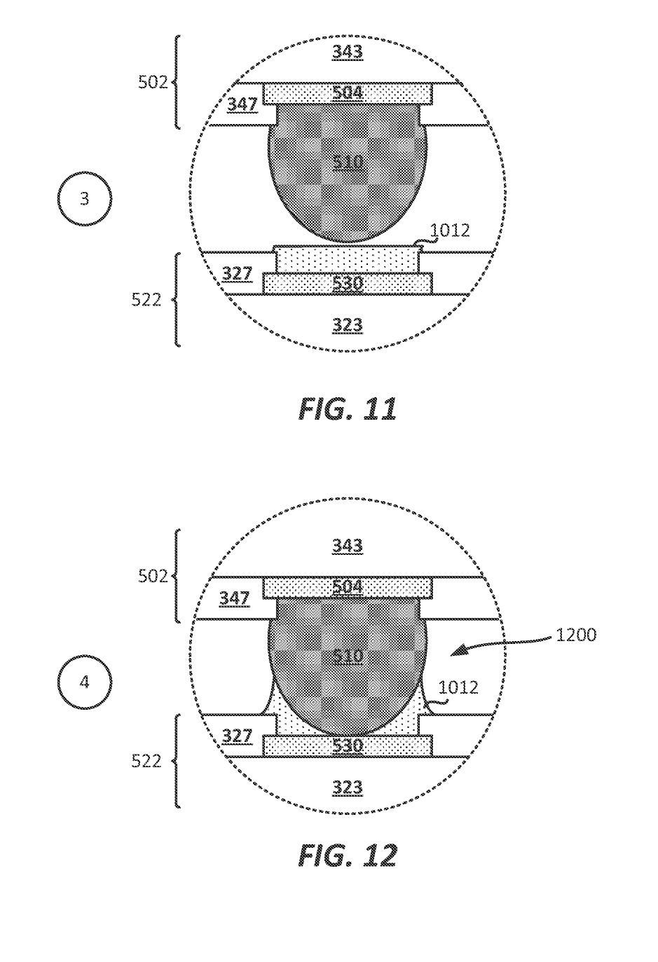

FIG. 11 and FIG. 12 respectively illustrate close up views of the solder joint structure of stages 3 and 4 of FIG. 10. Specifically, FIG. 11 illustrates a close up view of the substrate 502 being mounted on the package substrate 522 during stage 3 of FIG. 10. The substrate 502 includes the dielectric layer 343, the solder resist layer 347, and the pad 504. The solder ball 510 is coupled to the pad 504. The conductive material 1012 is located on the pad 530. The conductive material 1012 may fill some or all of the space between the solder resist layer 327 over the pad 530. The conductive material 1012 may also be over the solder resist layer 327. The conductive material 1012 may fill up to less than the solder resist layer 327.

FIG. 12 illustrates a close up view after the substrate 502 is coupled to the package substrate 522 during stage 4 of FIG. 10. As shown in FIG. 12, the solder joint structure 1200 (which includes the solder ball 510 and the conductive material 1012) is coupled to the pad 504 and the pad 530. The solder ball 510 may be adapted or configured as a mechanical stop during the mounting of the substrate 502 to the package substrate 522.

### Exemplary Sequence for Providing/Fabricating an Integrated Device Package Comprising Solder Joint Structure

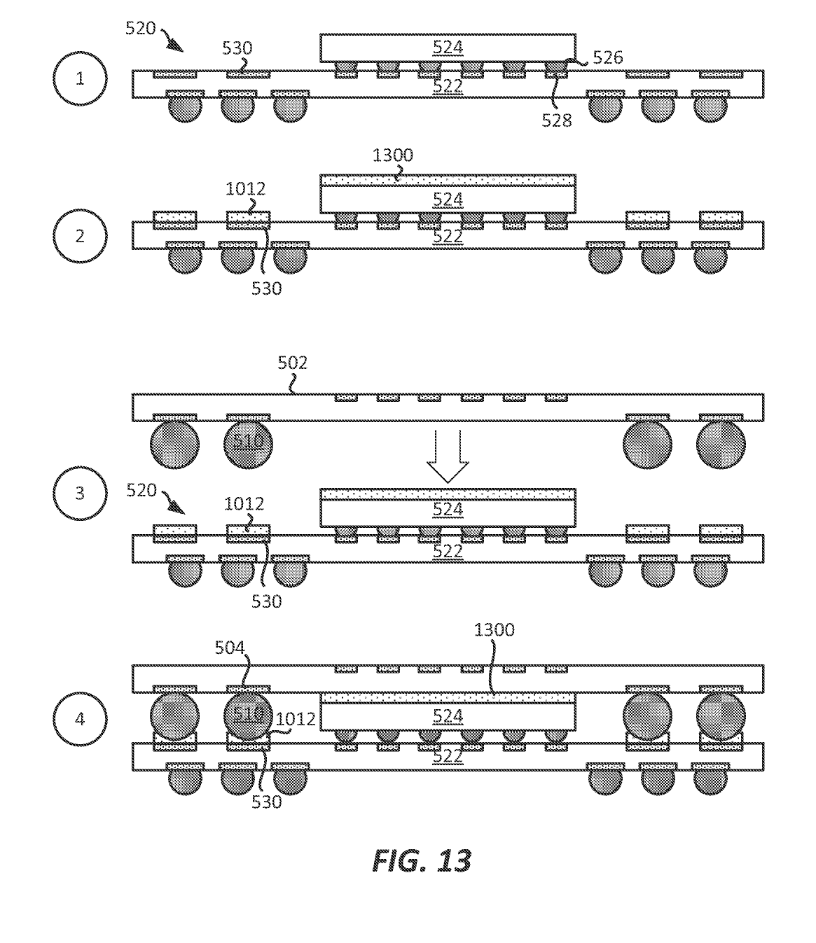

In some implementations, providing/fabricating an integrated device package (e.g., integrated circuit device) that includes a solder joint structure includes several processes. FIG. 13 illustrates an exemplary sequence for providing/fabricating an integrated device package (e.g., integrated circuit device) that includes a solder joint structure. In some implementations, the sequence of FIG. 13 may be used to provide/fabricate the integrated device packages of FIGS. 3-4 and/or other integrated device packages described in the present disclosure. However, for the purpose of simplification, FIG. 13 will be described in the context of providing/fabricating the integrated device package of FIG. 4.

It should be noted that the sequence of FIG. 13 may combine one or more stages in order to simplify and/or clarify the sequence for providing an integrated device package (e.g., integrated circuit device). In some implementations, the order of the processes may be changed or modified.

Stage 1 illustrates a state after an integrated device package 520 is provided. The integrated device package 520 includes a first package substrate 522 and a die 524. In some implementations, the first package substrate 522 is the package substrate 322 of FIG. 3. The first package substrate 522 includes a first set of pads 528 and a second set of pads 530. The first package substrate 522 may include one or more dielectric layers (e.g., dielectric layer 323) and the first solder resist layer 327. The first die 524 is coupled to the first package substrate 522 through a first set of solder balls 526. Specifically, the first die 524 is coupled to the first set of pads 528 through the first set of solder balls 526.

Stage 2 illustrates after a conductive material 1012 is provided (e.g., formed) on at least pad 530. Different implementations may provide the conductive material 1012 on the pad 530 differently. For example, the conductive material may be deposited on the pad 530. In some implementations, the conductive material 1012 is an electrically conductive material. Different implementations may use different materials for the conductive material 1012. The conductive material may be homogeneous or heterogeneous. In some implementations, the conductive material may include a material that is viscous before the material is cured and/or solidified (e.g., solidified after being heated). In some implementations, a viscous material is a material that is between a solid state and a liquid state. In some implementations, the conductive material may include a heterogeneous material that includes at least two materials. For example, the heterogeneous material may include a first electrically conductive material and a second electrically conductive material (e.g., small conductive fills, beads or pellets). In another example, the heterogeneous material may includes a first non-electrically conductive material and a second electrically conductive material. In some implementations, the conductive material 1012 has a lower melting point temperature, curing temperature, and/or solidification temperature than the melting point temperature of a solder ball.

Stage 2 also illustrates a layer 1300 located on the die 524. In some implementations, the layer 1300 is an adhesive layer or adhesive material that is coupled to the die 524. In some implementations, the layer 1300 may be adapted or configured to operate as mechanical stop when the package substrate 502 is mounted or coupled to the integrated device package 520. The layer 1300 may be used to ensure that the substrate 502 does not overly compress the solder balls onto the integrated device package 520.

Stage 3 illustrates a state as the substrate 502 is mounted to the integrated device package 520. The substrate 502 may be an interposer. The substrate 502 may be a package substrate of an integrated device package. In some implementations, the substrate 502 is the second package substrate 342 of FIG. 3. The substrate 502 includes one or more dielectric layers (e.g., dielectric layer 343), at least one pad 504, and a solder resist layer (e.g., solder resist layer 347). The substrate 502 is coupled to at least one solder ball (e.g., solder ball 510).

Stage 4 illustrates a state after the substrate 502 is coupled to the first package substrate 522. At least one solder joint structure is formed between the substrate 502 and the first package substrate 522. The solder joint structure may include the solder ball 510 and the conductive material 512. The layer 1300 is located between the die 524 and the substrate 502.

In some implementations, stage 4 illustrates a state after the solder joint structure has been cured and/or solidified (e.g., heated and solidified). In some implementations, the solder joint structure is cured and/or solidified using a temperature that is less than the melting point temperature (e.g., less than about 220 Celsius) of the solder ball 510. In such an instances, the solder ball 510 remains a solid and acts a mechanical stop, while the conductive material 512 coats, wets and fills voids and/or cavities that may exist between the solder ball 510 and the pad 530. This process ensures a solid and reliable joint between the two substrates.

In some implementations, a second die (e.g., die 340) may be placed on the substrate 502 before, during, or after stage 4.

### Exemplary Method for Providing/Fabricating an Integrated Device Package Comprising Solder Joint Structure

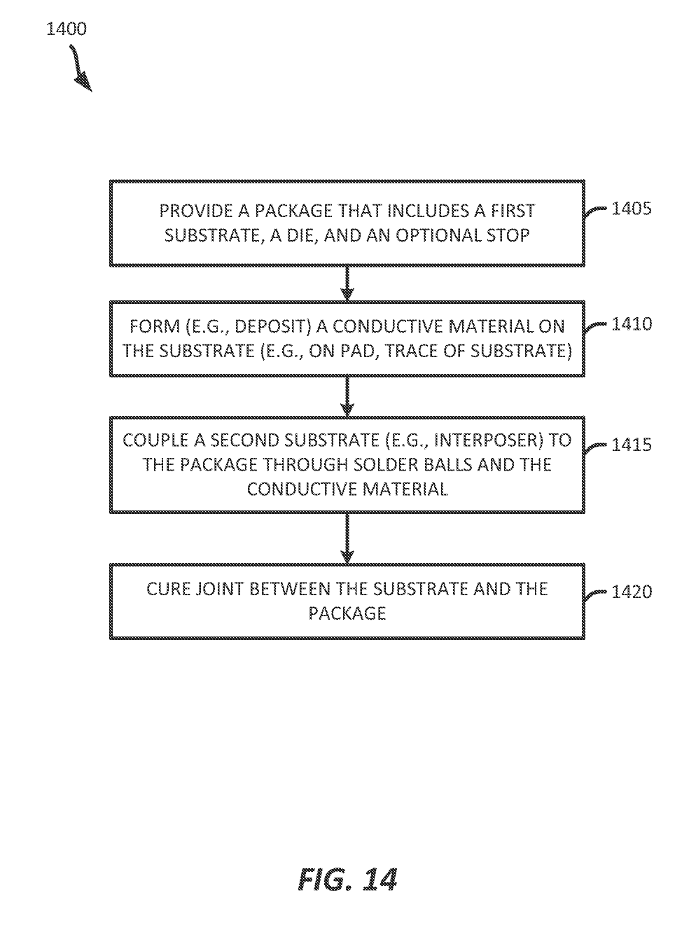

FIG. 14 illustrates an exemplary flow diagram of a method 1400 for providing/fabricating an integrated device package (e.g., integrated circuit device) that includes a solder joint structure. In some implementations, the method of FIG. 14 may be used to provide/fabricate the integrated device package (e.g., integrated circuit device) that includes a solder joint structure of FIGS. 3-4.

It should be noted that the flow diagram of FIG. 14 may combine one or more step and/or processes in order to simplify and/or clarify the method for providing an integrated device package. In some implementations, the order of the processes may be changed or modified.

The method provides (at 1405) an integrated device package. The integrated device package may include a first package substrate and a die. In some implementations, the first package substrate 522 is the package substrate 322 of FIG. 3. The first package substrate includes a first set of pads and a second set of pads. The first package substrate may include one or more dielectric layers (e.g., dielectric layer 323) and a first solder resist layer. The first die is coupled to the first package substrate through a first set of solder balls. Specifically, the first die is coupled to the first set of pads through the first set of solder balls. In some implementations, a layer is located on the die. In some implementations, the layer is an adhesive layer or adhesive material that is coupled to the die. In some implementations, the layer may be adapted or configured to operate as mechanical stop when the package substrate is mounted or coupled to the integrated device package. The layer may be used to ensure that the substrate does not overly compress the solder balls onto the integrated device package.

The method forms (at 1410) a conductive material on the package substrate (e.g., pad of package substrate). Different implementations may form the conductive material on the pad differently. For example, the conductive material is deposited on the pad. In some implementations, the conductive material is an electrically conductive material. Different implementations may use different materials for the conductive material. The conductive material may be homogeneous or heterogeneous. In some implementations, the conductive material may include a material that is viscous before the material is cured and/or solidified (e.g., solidified after being heated). In some implementations, a viscous material is a material that is between a solid state and a liquid state. In some implementations, the conductive material may include a heterogeneous material that includes at least two materials. For example, the heterogeneous material may include a first electrically conductive material and a second electrically conductive material (e.g., small conductive fills, beads or pellets). In another example, the heterogeneous material may includes a first non-electrically conductive material and a second electrically conductive material. In some implementations, the conductive material has a lower melting point temperature, curing temperature, and/or solidification temperature than the melting point temperature of a solder ball.

The method then couples (at 1415) a substrate to the integrated device package. The substrate may be an interposer. The substrate may be a package substrate of an integrated device package. In some implementations, the substrate is the package substrate 342 of FIG. 3. The substrate includes one or more dielectric layers (e.g., dielectric layer 343), at least one pad (e.g., pad 504), and a solder resist layer (e.g., solder resist layer 347). The substrate is coupled to at least one solder ball (e.g., solder ball 510).

In some implementations, when the substrate is coupled to the integrated device package, at least one solder joint structure is formed between the substrate and the integrated device package, where the solder joint structure includes a solder ball and a conductive material.

The method cures and/or solidifies (at 1420) the solder joint structure between the first substrate and the second substrate. In some implementations, the solder joint structure is cured and/or solidified using a temperature that is less than the melting point temperature (e.g., less than about 220 Celsius) of the solder ball, but higher than the melting point temperature, curing temperature, and/or solidification temperature of the conductive material. In such an instances, the solder ball remains a solid and acts a mechanical stop, while the conductive material coats, wets and fills voids and/or cavities that may exist between the solder ball and the pad of the package substrate. In some implementations, the use of the conductive material bypasses the use (e.g., does not require the use) of a solder reflow process and/or flux cleaning process, thereby reducing the cost of fabricating/manufacturing the device.

### Exemplary Solder Joint Structures

FIGS. 3-7 illustrate examples of solder joint structures that may be implemented to couple two substrates (e.g., package substrate, interposer). However, in some implementations, the solder joint structure may have a different configuration and/or may be coupled to the substrates differently. FIGS. 15-20 illustrate various examples of how different solder joint structures may be coupled to two substrates.

FIG. 15 illustrates a solder joint structure 1505 between the first package substrate 322 and the second package substrate 342. The solder joint structure 1505 includes the solder ball 356 and the conductive material 1507. The conductive material 1507 may be similar to the conductive material 366 and/or 466. As shown in FIG. 15, the solder ball 356 is not in direct contact with the pad 326 of the first package substrate 322. However, the solder ball 356 is indirectly coupled (e.g., electrically coupled) with the pad 326 through the conductive material 1507.

FIG. 16 illustrates a solder joint structure 1605 between the first package substrate 322 and the second package substrate 342. The solder joint structure 1605 includes the solder ball 356 and the conductive material 1507. The conductive material 1507 may be similar to the conductive material 366 and/or 466. A solder layer 1603 is located on the pad 326. In some implementations, the solder layer 1603 and the pad 326 is collectively referred as a solder on pad (SOP). As shown in FIG. 16, the solder joint structure 1605 is coupled to the solder layer 1603. The solder ball 356 is not in direct contact with the pad 326 of the first package substrate 322. However, the solder ball 356 is indirectly coupled (e.g., electrically coupled) with the pad 326 through the conductive material 1507 and/or the solder layer 1603. Similarly to FIG. 15, it is noted that the solder ball 356 does not need to be in direct contact with the solder layer 1603.

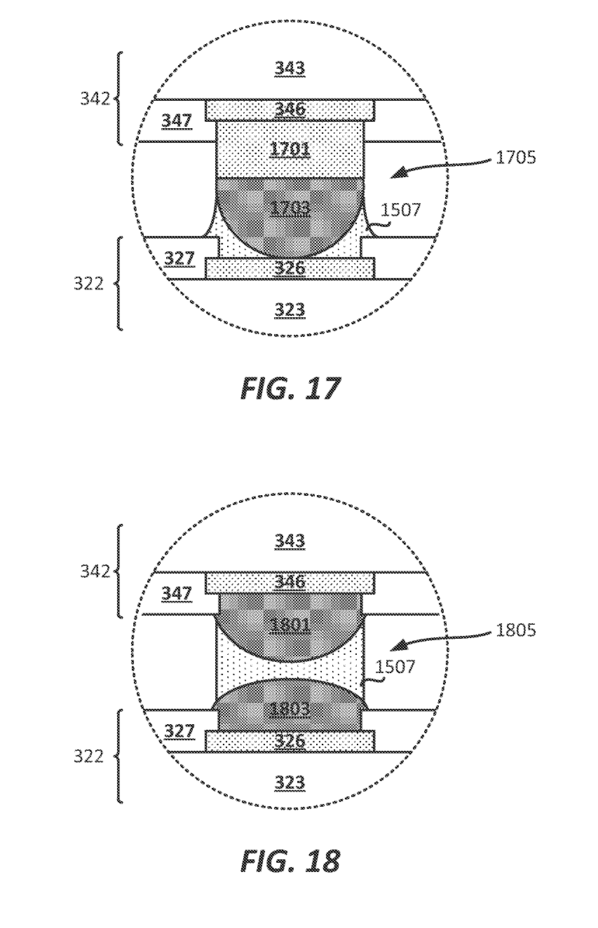

FIG. 17 illustrates a solder joint structure 1705 between the first package substrate 322 and the second package substrate 342. The solder joint structure 1705 includes a conductive pillar 1701, a solder ball 1703 and the conductive material 1507. The conductive material 1507 may be similar to the conductive material 366 and/or 466. As shown in FIG. 17, the conductive pillar 1701 is coupled to the pad 346 and the solder ball 1703. In some implementations, the conductive pillar 1701 may be part of the pad 346. The solder ball 1703 is coupled to the pad 326 of the first package substrate 322. The conductive material 1507 is coupled to the solder ball 1703 and the pad 326 of the first package substrate 322. Similarly to FIG. 15, it is noted that the solder ball 1703 does not need to be in direct contact with the pad 326 of the first package substrate 322.

FIG. 18 illustrates a solder joint structure 1805 between the first package substrate 322 and the second package substrate 342. The solder joint structure 1805 includes a first solder ball 1801, the conductive material 1507, and a second solder ball 1803. The conductive material 1507 may be similar to the conductive material 366 and/or 466. The first solder ball 1801 is coupled to the pad 346 of the second package substrate 342. The second solder ball 1803 is coupled to the pad 326 of the first package substrate 322. The conductive material 1507 is coupled to the first solder ball 1801 and the second solder ball 1803. In some implementations, the first solder ball 1801 is directly coupled to the second solder ball 1803.

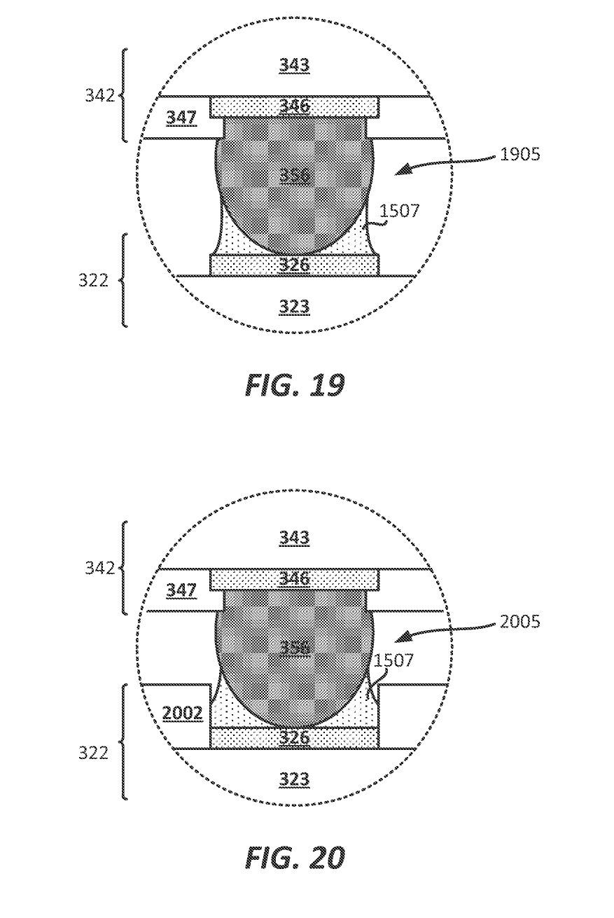

FIG. 19 illustrates a solder joint structure 1905 between the first package substrate 322 and the second package substrate 342. The solder joint structure 1905 includes the solder ball 356 and the conductive material 1507. The conductive material 1507 may be similar to the conductive material 366 and/or 466. As shown in FIG. 19, the first package substrate 322 does not include a solder resist layer. Similarly to FIG. 15, it is noted that the solder ball 356 does not need to be in direct contact with the pad 326 of the first package substrate 322.

FIG. 20 illustrates a solder joint structure 2005 between the first package substrate 322 and the second package substrate 342. The solder joint structure 2005 includes the solder ball 356 and the conductive material 1507. The conductive material 1507 may be similar to the conductive material 366 and/or 466. As shown in FIG. 20, the first package substrate 322 includes a layer 2002. Different implementations may use different materials for the layer 2002. For example, the layer 2002 may includes one of a dielectric layer, an encapsulation layer (e.g., mold compound), and/or a polymer. Similarly to FIG. 15, it is noted that the solder ball 356 does not need to be in direct contact with the pad 326 of the first package substrate 322.

The conductive material 1507 described in FIGS. 15-20 may be a homogeneous material or a heterogeneous material, as previously described above in at least FIGS. 3-4.

FIGS. 3-7 and 15-20 illustrates various examples of how solder may be coupled (e.g., directly coupled or indirectly coupled) to a pad or trace on a package substrate. In some implementations, the solder (e.g., solder ball 356) does not touch the pad (e.g., pad 326), as illustrated in FIG. 15. In some implementations, the solder is directly coupled to (e.g., touches) only a portion of the pad (e.g., pad 326), as illustrated in FIG. 17. In some implementations, the solder touches the entire pad (e.g., pad 326), as illustrated in FIG. 18.

It should be noted that FIGS. 15-20 merely illustrate examples of solder joint structures. In some implementations, other solder joint structures may be combinations of different components of the solder joint structures shown in FIGS. 15-20. Moreover, the thickness of the pads (e.g., pads 326, 346) may vary (e.g., thicker, thinner). In some implementations, the solder joint structures may be coupled to traces instead of pads. In some implementations, a pad is a wider version of a trace. In some implementations, the solder joint structures may include the pads and/or traces to which they are coupled to. For example, a solder joint structure may include a solder ball, a conductive material, and pad(s) (e.g., first pad, second pad).

### Exemplary Semi-Additive Patterning (SAP) Process

Various interconnects (e.g., traces, vias, pads) are described in the present disclosure. These interconnects may be formed in the package substrate and/or the redistribution portion of the integrated device package. In some implementations, these interconnects may includes one or more metal layers. For example, in some implementations, these interconnects may include a first metal seed layer and a second metal layer. The metal layers may be provided (e.g., formed) using different plating processes. Below are detailed examples of interconnects (e.g., traces, vias, pads) with seed layers and how these interconnects may be formed using different plating processes. For example, the processes below may be used to fabricate and/or form the pad 326 and/or pad 346.

Different implementations may use different processes to form and/or fabricate the metal layers (e.g., interconnects, redistribution layer, under bump metallization layer, protrusion). In some implementations, these processes include a semi-additive patterning (SAP) process and a damascene process. These various different processes are further described below. It should be noted that other processes can be used, as well such as modified SAP (mSAP).

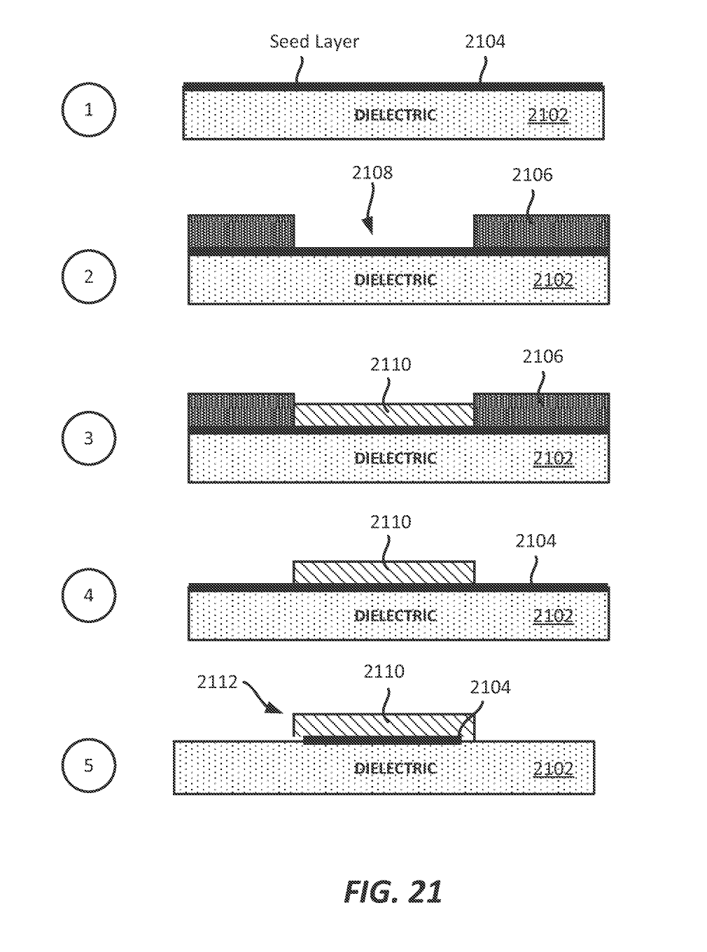

FIG. 21 illustrates a sequence for forming an interconnect using a semi-additive patterning (SAP) process to provide and/or form an interconnect in one or more dielectric layer(s). As shown in FIG. 21, stage 1 illustrates a state of an integrated device (e.g., substrate) after a dielectric layer 2102 is provided (e.g., formed). In some implementations, stage 1 illustrates that the dielectric layer 2102 includes a first metal layer 2104. The first metal layer 2104 is a seed layer in some implementations. In some implementations, the first metal layer 2104 may be provided (e.g., formed) on the dielectric layer 2102 after the dielectric layer 2102 is provided (e.g., received or formed). Stage 1 illustrates that the first metal layer 2104 is provided (e.g., formed) on a first surface of the dielectric layer 2102. In some implementations, the first metal layer 2104 is provided by using a deposition process (e.g., PVD, CVD, plating process).

Stage 2 illustrates a state of the integrated device after a photo resist layer 2106 (e.g., photo develop resist layer) is selectively provided (e.g., formed) on the first metal layer 2104. In some implementations, selectively providing the resist layer 2106 includes providing a first resist layer 2106 on the first metal layer 2104 and selectively removing portions of the resist layer 2106 by developing (e.g., using a development process). Stage 2 illustrates that the resist layer 2106 is provided such that a cavity 2108 is formed.

Stage 3 illustrates a state of the integrated device after a second metal layer 2110 is formed in the cavity 2108. In some implementations, the second metal layer 2110 is formed over an exposed portion of the first metal layer 2104. In some implementations, the second metal layer 2110 is provided by using a deposition process (e.g., plating process).

Stage 4 illustrates a state of the integrated device after the resist layer 2106 is removed. Different implementations may use different processes for removing the resist layer 2106.

Stage 5 illustrates a state of the integrated device after portions of the first metal layer 2104 are selectively removed. In some implementations, one or more portions of the first metal layer 2104 that is not covered by the second metal layer 2110 is removed. As shown in stage 5, the remaining first metal layer 2104 and the second metal layer 2110 may form and/or define an interconnect 2112 (e.g., trace, vias, pads) in an integrated device and/or a substrate. In some implementations, the first metal layer 2104 is removed such that a dimension (e.g., length, width) of the first metal layer 2104 underneath the second metal layer 2110 is smaller than a dimension (e.g., length, width) of the second metal layer 2110, which can result in an undercut, as shown at stage 5 of FIG. 21. In some implementations, the above mentioned processes may be iterated several times to provide and/or form several interconnects in one or more dielectric layers of an integrated device and/or substrate.

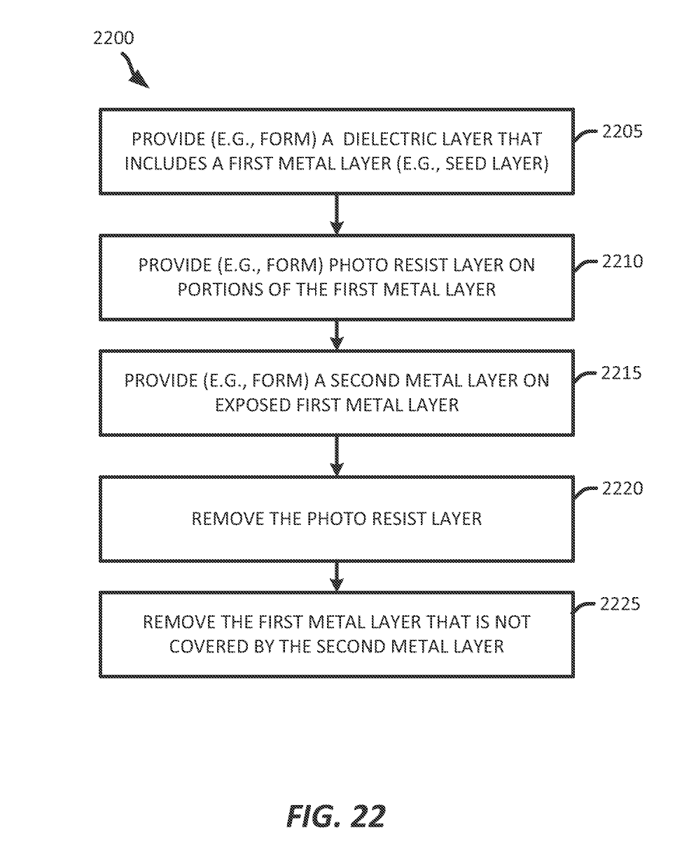

FIG. 22 illustrates a flow diagram for a method for using a (SAP) process to provide and/or form an interconnect in one or more dielectric layer(s). The method provides (at 2205) a dielectric layer (e.g., dielectric layer 2102). In some implementations, providing the dielectric layer includes forming the dielectric layer. In some implementations, providing the dielectric layer includes forming a first metal layer (e.g., first metal layer 2104). The first metal layer is a seed layer in some implementations. In some implementations, the first metal layer may be provided (e.g., formed) on the dielectric layer after the dielectric layer is provided (e.g., received or formed). In some implementations, the first metal layer is provided by using a deposition process (e.g., physical vapor deposition (PVD) or plating process).

The method selectively provides (at 2210) a photo resist layer (e.g., a photo develop resist layer 2106) on the first metal layer. In some implementations, selectively providing the resist layer includes providing a first resist layer on the first metal layer and selectively removing portions of the resist layer (which provides one or more cavities).

The method then provides (at 2215) a second metal layer (e.g., second metal layer 2110) in the cavity of the photo resist layer. In some implementations, the second metal layer is formed over an exposed portion of the first metal layer. In some implementations, the second metal layer is provided by using a deposition process (e.g., plating process).

The method further removes (at 2220) the resist layer. Different implementations may use different processes for removing the resist layer. The method also selectively removes (at 2225) portions of the first metal layer. In some implementations, one or more portions of the first metal layer that is not covered by the second metal layer are removed. In some implementations, any remaining first metal layer and second metal layer may form and/or define one or more interconnects (e.g., trace, vias, pads) in an integrated device and/or a substrate. In some implementations, the above mentioned method may be iterated several times to provide and/or form several interconnects in one or more dielectric layers of an integrated device and/or substrate.

### Exemplary Damascene Process

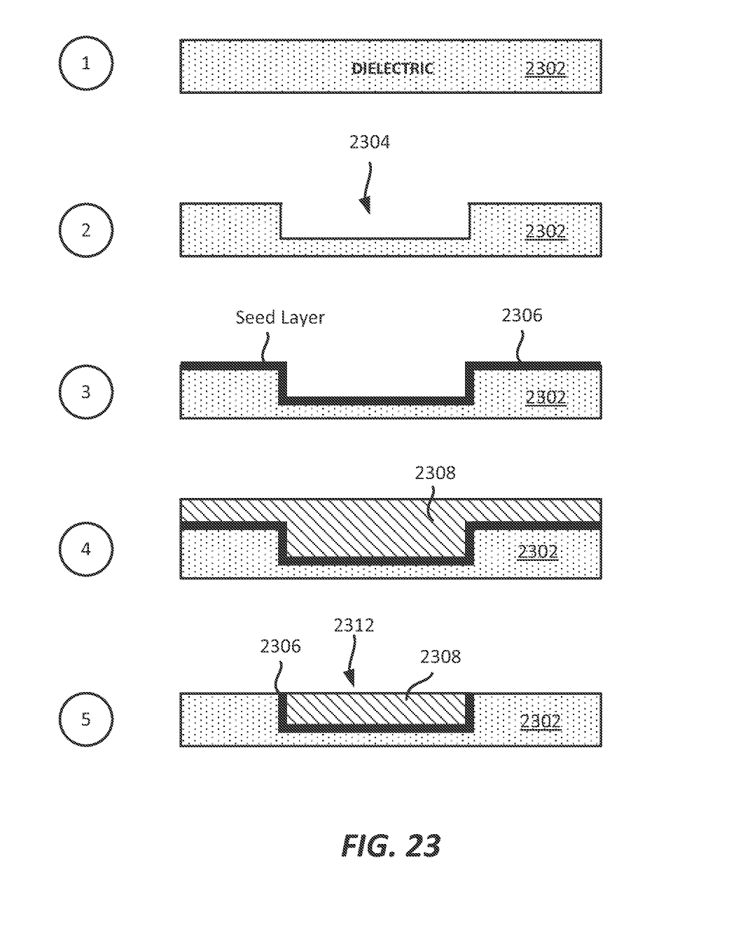

FIG. 23 illustrates a sequence for forming an interconnect using a damascene process to provide and/or form an interconnect in a dielectric layer. As shown in FIG. 23, stage 1 illustrates a state of an integrated device after a dielectric layer 2302 is provided (e.g., formed). In some implementations, the dielectric layer 2302 is an inorganic layer (e.g., inorganic film).

Stage 2 illustrates a state of an integrated device after a cavity 2304 is formed in the dielectric layer 2302. Different implementations may use different processes for providing the cavity 2304 in the dielectric layer 2302.

Stage 3 illustrates a state of an integrated device after a first metal layer 2306 is provided on the dielectric layer 2302. As shown in stage 3, the first metal layer 2306 provided on a first surface of the dielectric layer 2302. The first metal layer 2306 is provided on the dielectric layer 2302 such that the first metal layer 2306 takes the contour of the dielectric layer 2302 including the contour of the cavity 2304. The first metal layer 2306 is a seed layer in some implementations. In some implementations, the first metal layer 2306 is provided by using a deposition process (e.g., physical vapor deposition (PVD), Chemical Vapor Deposition (CVD) or plating process).

Stage 4 illustrates a state of the integrated device after a second metal layer 2308 is formed in the cavity 2304 and a surface of the dielectric layer 2302. In some implementations, the second metal layer 2308 is formed over an exposed portion of the first metal layer 2306. In some implementations, the second metal layer 2308 is provided by using a deposition process (e.g., plating process).

Stage 5 illustrates a state of the integrated device after the portions of the second metal layer 2308 and portions of the first metal layer 2306 are removed. Different implementations may use different processes for removing the second metal layer 2308 and the first metal layer 2306. In some implementations, a chemical mechanical planarization (CMP) process is used to remove portions of the second metal layer 2308 and portions of the first metal layer 2306. As shown in stage 5, the remaining first metal layer 2306 and the second metal layer 2308 may form and/or define an interconnect 2312 (e.g., trace, vias, pads) in an integrated device and/or a substrate. As shown in stage 5, the interconnect 2312 is formed in such a way that the first metal layer 2306 is formed on the base portion and the side portion(s) of the second metal layer 2310. In some implementations, the cavity 2304 may include a combination of trenches and/or holes in two levels of dielectrics so that via and interconnects (e.g., metal traces) may be formed in a single deposition step, In some implementations, the above mentioned processes may be iterated several times to provide and/or form several interconnects in one or more dielectric layers of an integrated device and/or substrate.

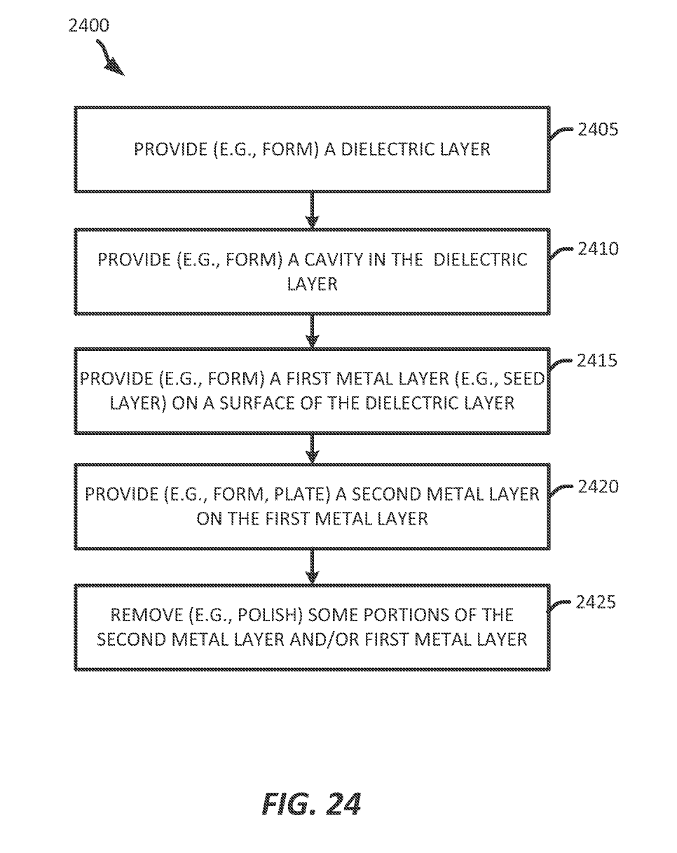

FIG. 24 illustrates a flow diagram of a method 2400 for forming an interconnect using a damascene process to provide and/or form an interconnect in a dielectric layer. The method provides (at 2405) a dielectric layer (e.g., dielectric layer 2302). In some implementations, providing a dielectric layer includes forming a dielectric layer. In some implementations, providing a dielectric layer includes receiving a dielectric layer from a supplier. In some implementations, the dielectric layer is an inorganic layer (e.g., inorganic film).

The method forms (at 2410) at least one cavity (e.g., cavity 2304) in the dielectric layer. Different implementations may use different processes for providing the cavity in the dielectric layer.

The method provides (at 2415) a first metal layer (e.g., first metal layer 2306) on the dielectric layer. In some implementations, the first metal layer is provided (e.g., formed) on a first surface of the dielectric later. In some implementations, the first metal layer is provided on the dielectric layer such that the first metal layer takes the contour of the dielectric layer including the contour of the cavity. The first metal layer is a seed layer in some implementations. In some implementations, the first metal layer 2306 is provided by using a deposition process (e.g., PVD, CVD or plating process).

The method provides (at 2420) a second metal layer (e.g., second metal layer 2308) in the cavity and a surface of the dielectric layer. In some implementations, the second metal layer is formed over an exposed portion of the first metal layer. In some implementations, the second metal layer is provided by using a deposition process (e.g., plating process). In some implementations, the second metal layer is similar or identical to the first metal layer. In some implementations, the second metal layer is different than the first metal layer.

The method then removes (at 2425) portions of the second metal layer and portions of the first metal layer. Different implementations may use different processes for removing the second metal layer and the first metal layer. In some implementations, a chemical mechanical planarization (CMP) process is used to remove portions of the second metal layer and portions of the first metal layer. In some implementations, the remaining first metal layer and the second metal layer may form and/or define an interconnect (e.g., interconnect 2312). In some implementations, an interconnect may include one of at least a trace, a via, and/or a pad) in an integrated device and/or a substrate. In some implementations, the interconnect is formed in such a way that the first metal layer is formed on the base portion and the side portion(s) of the second metal layer. In some implementations, the above mentioned method may be iterated several times to provide and/or form several interconnects in one or more dielectric layers of an integrated device and/or substrate.

### Exemplary Electronic Devices

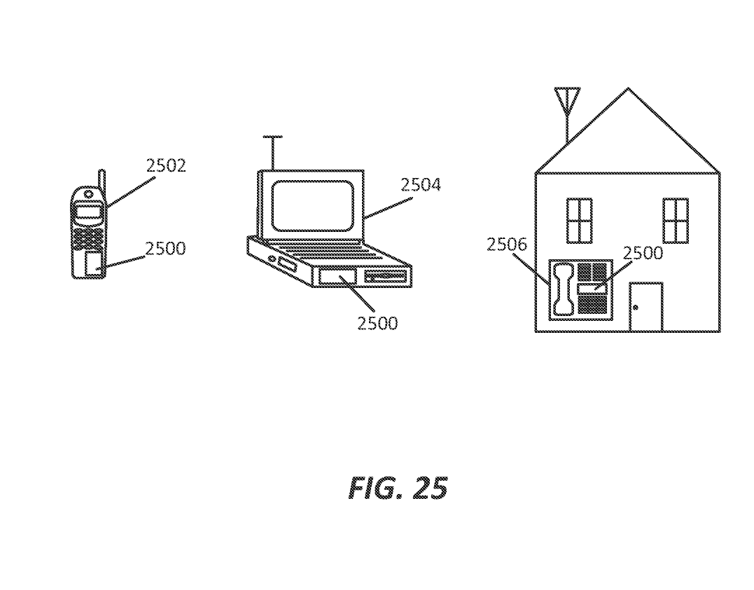

FIG. 25 illustrates various electronic devices that may be integrated with any of the aforementioned integrated device, semiconductor device, integrated circuit, die, interposer, package or package-on-package (PoP). For example, a mobile phone device 2502, a laptop computer device 2504, and a fixed location terminal device 2506 may include an integrated device 2500 as described herein. The integrated device 2500 may be, for example, any of the integrated circuits, dies, integrated devices, integrated device packages, integrated circuit devices, package-on-package devices described herein. The devices 2502, 2504, 2506 illustrated in FIG. 25 are merely exemplary. Other electronic devices may also feature the integrated device 2500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

One or more of the components, steps, features, and/or functions illustrated in FIGS. 3, 4, 5, 6, 7, 8, 9, 10, 11, 12, 13, 14, 15, 16, 17, 18, 19, 20, 21, 22, 23, 24 and/or 25 may be rearranged and/or combined into a single component, step, feature or function or embodied in several components, steps, or functions. Additional elements, components, steps, and/or functions may also be added without departing from the disclosure. It should also be noted that FIGS. 3, 4, 5, 6, 7, 8, 9, 10, 11, 12, 13, 14, 15, 16, 17, 18, 19, 20, 21, 22, 23, 24 and/or 25 and its corresponding description in the present disclosure is not limited to dies and/or ICs. In some implementations, FIGS. 3, 4, 5, 6, 7, 8, 9, 10, 11, 12, 13, 14, 15, 16, 17, 18, 19, 20, 21, 22, 23, 24 and/or 25 and its corresponding description may be used to manufacture, create, provide, and/or produce integrated devices. In some implementations, a device may include a die, an integrated device, a die package, an integrated circuit (IC), an integrated device package, a wafer, a semiconductor device, a package on package (PoP) device, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another-even if they do not directly physically touch each other.

A ‘set’ of objects may include one or more objects. For example, a set of solder balls may include one or more solder balls. A ‘set’ of interconnects may include one or more interconnects. A set of solder joint structures may include one or more solder joint structures. A set of pads may include one or more pads.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An integrated circuit device comprising:
a first package substrate;
a first die coupled to the first package substrate;
a second package substrate; and
a solder joint structure coupled to the first package substrate and the second package substrate, the solder joint structure comprising:
a solder comprising a first melting point temperature; and
a conductive material comprising a second melting point temperature that is less than the first melting point temperature.

2. The integrated circuit device of claim 1, wherein the conductive material is one of at least a homogeneous material and/or a heterogeneous material.

3. The integrated circuit device of claim 1, wherein the conductive material includes a first electrically conductive material and a second material.

4. The integrated circuit device of claim 1, wherein the second melting point temperature is a temperature at which the conductive material begins to melt.

5. The integrated circuit device of claim 1, wherein the first package substrate includes a first pad, and the second package substrate includes a second pad, wherein the solder joint structure is coupled to the first pad and the second pad.

6. The integrated circuit device of claim 5, wherein the solder is coupled to the first pad.

7. The integrated circuit device of claim 1, further comprising a plurality of solder joint structures comprising a pitch of about 275 microns (μm) or less.

8. The integrated circuit device of claim 1, further comprising a layer between the first die and the second package substrate.

9. The integrated circuit device of claim 8, wherein the layer is an adhesive layer.

10. The integrated circuit device of claim 1, wherein the integrated circuit device is incorporated into a device selected from a group comprising of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in a automotive vehicle, and further including the device.

11. A method for fabricating an integrated circuit device, comprising:
providing a first package substrate;
coupling a first die to the first package substrate;
providing a second package substrate; and
forming a solder joint structure on the first package substrate and the second package substrate, wherein forming the solder joint structure comprises:
selecting a solder comprising a first melting point temperature;
forming the solder on the second package substrate;
selecting a conductive material comprising a second melting point temperature that is less than the first melting point temperature; and
coupling the conductive material to the solder.

12. The method of claim 11, wherein the conductive material is one of at least a homogeneous material and/or a heterogeneous material.

13. The method of claim 11, wherein the conductive material includes a first electrically conductive material and a second material.

14. The method of claim 11, wherein the second melting point temperature is a temperature at which the conductive material begins to melt.

15. The method of claim 11, wherein the first package substrate includes a first pad, and the second package substrate includes a second pad, wherein forming the solder joint structure comprises coupling the solder joint structure to the first pad and the second pad.

16. The method of claim 15, wherein forming the solder comprises coupling the solder to the first pad.

17. The method of claim 11, wherein forming solder joint structure comprises forming a plurality of solder joint structures comprising a pitch of about 275 microns (μm) or less.

18. The method of claim 11, further comprising forming a layer between the first die and the second package substrate.

19. The method of claim 18, wherein the layer is an adhesive layer.

20. The method of claim 11, wherein the integrated circuit device is incorporated into a device selected from a group comprising of a music player, a video player, an entertainment unit, a navigation device, a communications device, a mobile device, a mobile phone, a smartphone, a personal digital assistant, a fixed location terminal, a tablet computer, a computer, a wearable device, and a laptop computer, and further including the device.

21. An integrated circuit device comprising:
a first package substrate;
a first die coupled to the first package substrate;
a second package substrate; and
a solder joint structure coupled to the first package substrate and the second package substrate, the solder joint structure comprising:
a solder comprising a first melting point temperature; and
a conductive material comprising a second solidification temperature that is less than the first melting point temperature.

22. The integrated circuit device of claim 21, wherein the conductive material is one of at least a homogeneous material and/or a heterogeneous material.

23. The integrated circuit device of claim 21, wherein the conductive material includes a first electrically conductive material and a second material.

24. The integrated circuit device of claim 21, wherein the second solidification temperature is a temperature at which the conductive material begins to solidify.

25. The integrated circuit device of claim 21, wherein the first package substrate includes a first pad, and the second package substrate includes a second pad, wherein the solder joint structure is coupled to the first pad and the second pad.

26. The integrated circuit device of claim 25, wherein the solder is coupled to the first pad.

27. The integrated circuit device of claim 21, further comprising a plurality of solder joint structures comprising a pitch of about 275 microns (μm) or less.

28. The integrated circuit device of claim 21, further comprising a layer between the first die and the second package substrate.

29. The integrated circuit device of claim 28, wherein the layer is an adhesive layer.

30. The integrated circuit device of claim 21, wherein the integrated circuit device is incorporated into a device selected from a group comprising of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in a automotive vehicle, and further including the device.
